(19) United States
(12) Patent Application Publication
(10) Pub. No.: US 2024/0353972 A1
(43) Pub. Date: Oct. 24, 2024

(54) USER INTERFACE DISPLAY METHOD, ELECTRONIC DEVICE, MEDIUM, AND PROGRAM PRODUCT

(71) Applicant: HUAWEI TECHNOLOGIES CO., LTD., Shenzhen (CN)

(72) Inventor: Chao Bian, Nanjing (CN)

(73) Assignee: HUAWEI TECHNOLOGIES CO., LTD., Shenzhen (CN)

(21) Appl. No.: 18/761,341

(22) Filed: Jul. 2, 2024

Related U.S. Application Data
(63) Continuation of application No. PCT/CN2022/141119, filed on Dec. 22, 2022.

(30) Foreign Application Priority Data
Jan. 4, 2022 (CN) 202210002571.3

(51) Int. Cl. G06F 3/04817; G06F 3/04845; G06F 9/451

(52) U.S. Cl. CPC G06F 3/04817; G06F 3/04845; G06F 9/451

(57) ABSTRACT

A method includes: an electronic device displays a first user interface (UI) element and a second UI element on a screen. Further, the electronic device detects an operation performed on the first UI element and enables the first UI element to move correspondingly. When it is determined that the first UI element enters or leaves a target range associated with the second UI element, the electronic device enables at least one of the first UI element and the second UI element to produce an animation effect. A change degree of the animation effect is determined based at least on a first size of the first UI element or a second size of the second UI element.

### CROSS-REFERENCE TO RELATED APPLICATIONS

This application is a continuation of International Application No. PCT/CN2022/141119, filed on Dec. 22, 2022, which claims priority to Chinese Patent Application No. 202210002571.3, filed on Jan. 4, 2022. The disclosures of the aforementioned applications are hereby incorporated by reference in their entireties.

### TECHNICAL FIELD

The present disclosure generally relates to the field of information technologies, and more particularly, to a user interface display method, an electronic device, a computer-readable storage medium, and a computer program product.

### BACKGROUND

With the development of information technologies, an increasing number of electronic devices are equipped with various types of screens. Therefore, an overall display effect and a style of a user interface (UI) or a graphical user interface (GUI) on a screen of an electronic device become important factors that affect user experience. During construction of a UI framework, an animation effect has become an inseparable part. As performance of the electronic device such as a smartphone is improved, a UI animation effect of the electronic device is also developed. Animation effects with high refresh rates, high rendering degrees, and high complexity gradually appear. However, there is still room for further improvement of the UI animation effect on the screen of the electronic device, to provide better user experience.

### SUMMARY

Embodiments of the present disclosure relate to a technical solution for a magnetic force animation effect, and specifically provide a user interface display method, an electronic device, a computer-readable storage medium, and a computer program product.

According to a first aspect of the present disclosure, a user interface display method is provided. In the method, an electronic device displays a first user interface (UI) element and a second UI element on a screen. Further, the electronic device detects an operation performed on the first UI element and enables the first UI element to move correspondingly. When it is determined that the first UI element enters or leaves a target range associated with the second UI element, the electronic device enables at least one of the first UI element and the second UI element to produce an animation effect. A change degree of the animation effect is determined based at least on a first size of the first UI element or a second size of the second UI element. In this way, embodiments of the present disclosure present a dynamic effect that conforms to a natural magnetic force law and that is more consistent with life experience of a user, thereby enhancing vitality and a degree of humanization of the electronic device.

In some embodiments, the change degree of the animation effect is further determined based on speed information associated with the motion of the first UI element, and the speed information indicates at least one of the following: a speed at which the first UI element enters or leaves the target range; or an average speed of the first UI element in a target time period, where the target time period is determined based on a moment at which the first UI element enters or leaves the target range. In some embodiments, the change degree of the animation effect is directly proportional to the first size or the second size and inversely proportional to the speed indicated by the speed information. In this manner, a “magnetic force” animation effect provided in the present disclosure can further consider impact of a speed of a UI element on the animation effect, thereby providing more real interaction experience.

In some embodiments, the enabling at least one of the first UI element and the second UI element to produce an animation effect includes: enabling the at least one of the first UI element and the second UI element to move a target distance, where the change degree indicates a length of the target distance; or changing a visual feature of the at least one of the first UI element and the second UI element, where the visual feature includes at least one of the following: a size, a color, a shape, transparency, or brightness, and the change degree indicates a change magnitude of the visual feature. Based on such a manner, in embodiments of the present disclosure, a salient degree of the animation effect can be adjusted based on a “magnetic force” effect, thereby providing an effect such as magnetic force attraction or repulsion and providing more vivid interaction experience.

In some embodiments, the animation effect is determined based on a predefined curve that changes over time. The predefined curve is a Bézier curve or an elastic force curve. In this manner, in embodiments of the present disclosure, the motion of the UI element may be conveniently controlled based on the Bezier curve or the elastic force curve, so that the “magnetic force” animation effect better conforms to habit cognition of the user for a “magnetic attraction force” and a “repulsion force” in life, thereby further improving user experience.

In some embodiments, the animation effect includes a first animation effect produced by the second UI element at a first moment, the screen of the electronic device further displays a third UI element, and the method further includes: enabling the third UI element to produce a second animation effect at a second moment, where the second moment is later than the first moment. In some embodiments, the second moment is determined based on a distance from the third UI element to the first UI element at the first moment. In this manner, embodiments of the present disclosure can further provide an effect of “magnetic force” transfer, thereby further improving a sense of reality of an interaction.

In some embodiments, the enabling, in response to determining that the first UI element enters or leaves the target range associated with the second UI element, at least one of the first UI element and the second UI element to produce an animation effect includes: in response to detecting that the motion enables the first UI element to enter the target range at a third moment, enabling the at least one of the first UI element and the second UI element to produce the first animation effect; and in response to detecting that the motion enables the second UI element to leave the target range at a fourth moment and that a difference between the fourth moment and the third moment is less than an animation effect duration of the first animation effect: enabling the at least one of the first UI element and the second UI element to stop presenting the first animation effect; and enabling the at least one of the first UI element and the second UI element to start presenting the second animation effect. In this manner, embodiments of the present disclosure can provide an interruption mechanism related to a “magnetic force” effect, so that the user can obtain a more rapid interaction feedback.

In some embodiments, the target range is determined based on the second size of the second UI element. In some embodiments, the first UI element is a cursor element, the second UI element is a control element, and the enabling at least one of the first UI element and the second UI element to produce an animation effect includes: in response to determining that the first UI element enters the target range, enabling the second UI element to be switched from a first state to a floating state, where a size or a background board style of the second UI element in the floating state is different from that of the second UI element in the first state; or in response to determining that the first UI element leaves the target range, enabling the second UI element to exit the floating state. In this manner, embodiments of the present disclosure can enrich an interaction scenario of the UI element, thereby providing more real interaction experience.

In some embodiments, the method further includes: determining, based on a comparison between the target range and location information that is associated with the first UI element, that the first UI element enters or leaves the target range associated with the second UI element, where the location information indicates a central location or a boundary location of the first UI element. In this manner, embodiments of the present disclosure can more promptly trigger production of the “magnetic force” animation effect, thereby providing a more rapid animation effect feedback.

In some embodiments, a function of the user interface display method in the first aspect may be implemented by using at least one of an AAR file, a JAR file, and a system interface of the electronic device. In this manner, a capability or function of the “magnetic force” animation effect may be simply and conveniently implemented and provided to an application of the electronic device, for example, a desktop.

According to a second aspect of the present disclosure, a user interface display method is provided. In the method, an electronic device displays a first user interface UI element on a screen. The electronic device may receive an interaction action of a user. In addition, when determining that an interaction location corresponding to the interaction action enters or leaves a target range associated with the first UI element, the first UI element is enabled to produce an animation effect. A change degree of the animation effect is determined based on at least one of the following: speed information of the interaction action or a size of the first UI element. In this way, embodiments of the present disclosure present a dynamic effect that conforms to a natural magnetic force law, and can enrich interaction experience of the user.

According to a third aspect of the present disclosure, a user interface display method is provided. In the method, an electronic device displays a first user interface UI element and a second UI element on a screen. The electronic device may receive a drag operation performed on the first UI element. When determining that the drag operation is terminated at a target location and that the target location is within a target range associated with the second UI element, the electronic device enables the first UI element to produce an animation effect. A change degree of the animation effect is determined based at least on a first size of the first UI element or a second size of the second UI element. In this way, embodiments of the present disclosure present a dynamic effect that conforms to a natural magnetic force law, thereby enhancing vitality and a degree of humanization of the electronic device.

According to a fourth aspect of the present disclosure, an electronic device is provided. The electronic device includes a processor and a memory that stores instructions. When the instructions are executed by the processor, the electronic device is enabled to perform the method according to any one of the first aspect, the second aspect, and/or the third aspect and the implementations thereof.

According to a fifth aspect of the present disclosure, a computer-readable storage medium is provided. The computer-readable storage medium stores instructions. When the instructions are executed by an electronic device, the electronic device is enabled to perform the method according to any one of the first aspect, the second aspect, and/or the third aspect and the implementations thereof.

According to a sixth aspect of the present disclosure, a computer program product is provided. The computer program product includes instructions. When the instructions are executed by an electronic device, the electronic device is enabled to perform the method according to any one of the first aspect, the second aspect, and/or the third aspect and the implementations thereof.

It should be understood that the content described in the summary is not intended to limit a key or important feature of the present disclosure, and is not intended to limit the scope of the present disclosure. The following descriptions facilitate understanding of other features of the present disclosure.

### BRIEF DESCRIPTION OF DRAWINGS

The foregoing and other objectives, features, and advantages of embodiments of the present disclosure become easily understood by reading the following detailed descriptions with reference to the accompanying drawings. In the accompanying drawings, several embodiments of the present disclosure are shown by way of example and not limitation.

FIG. 1 is a schematic diagram of a hardware structure of an electronic device that may implement an embodiment of the present disclosure;

FIG. 2A and FIG. 2B are a schematic diagram of a change of a user interface according to some embodiments of the present disclosure;

FIG. 3A and FIG. 3B are schematic diagrams of a change trend of a UI element according to some embodiments of the present disclosure;

FIG. 4A is a schematic diagram of a change of a user interface according to some other embodiments of the present disclosure;

FIG. 4B is a schematic diagram of a change trend of a UI element according to some other embodiments of the present disclosure;

FIG. 5A and FIG. 5B are a schematic diagram of a change of a user interface according to some embodiments of the present disclosure;

FIG. 6A is a schematic diagram of a change of a user interface according to some other embodiments of the present disclosure;

FIG. 6B is a schematic diagram of a change trend of a UI element according to some other embodiments of the present disclosure;

FIG. 7A(1) and FIG. 7A(2) are a schematic diagram of a change of a user interface according to still some embodiments of the present disclosure;

FIG. 7B is a schematic diagram of a change trend of a UI element according to still some embodiments of the present disclosure;

FIG. 8A to FIG. 8C are schematic diagrams of a change of a user interface according to still some embodiments of the present disclosure;

FIG. 9A and FIG. 9B are schematic diagrams of a change of a user interface according to still some embodiments of the present disclosure;

FIG. 10A to FIG. 10C show examples of UI interaction processes according to some embodiments of the present disclosure;

FIG. 11 shows an example of a UI interaction process according to some other embodiments of the present disclosure;

FIG. 12 shows an example of a UI interaction process according to some other embodiments of the present disclosure;

FIG. 13 shows an example of a UI interaction process according to still some embodiments of the present disclosure;

FIG. 14 shows an example of a UI interaction process according to still some embodiments of the present disclosure;

FIG. 15 is a schematic diagram of an animation process and related control logic of a “magnetic force” animation effect according to an embodiment of the present disclosure;

FIG. 16 is a schematic diagram of a system framework for implementing a capability or function of a “magnetic force” animation effect according to an embodiment of the present disclosure;

FIG. 17 is a schematic diagram of a relationship between an application side and a UI framework side that are related to a capability or function of a “magnetic force” animation effect according to an embodiment of the present disclosure;

FIG. 18 is a schematic diagram of a specific description of three manners of implementing a capability or function of a “magnetic force” animation effect according to an embodiment of the present disclosure;

FIG. 19 is a flowchart of an example process of a user interface display method according to some embodiments of the present disclosure;

FIG. 20 is a flowchart of an example process of a user interface display method according to some embodiments of the present disclosure; and

FIG. 21 is a flowchart of an example process of a user interface display method according to some embodiments of the present disclosure.

Throughout all the accompanying drawings, same or similar reference numerals represent same or similar components.

### DESCRIPTION OF EMBODIMENTS

The following describes the principle and spirit of the present disclosure with reference to several example embodiments shown in the accompanying drawings. It should be understood that these specific embodiments are described merely to enable a person skilled in the art to better understand and implement the present disclosure, but are not intended to limit the scope of the present disclosure in any manner. In the following descriptions and claims, unless otherwise defined, all technical and scientific terms used in this specification have meanings as those commonly understood by a person of ordinary skill in the art to which this specification belongs.

As used in this specification, the term “include” and similar terms should be understood as open inclusion, that is, “include but not limited to”. The term “based on” should be understood as “at least partially based on”. The term “one embodiment” or “the embodiment” should be understood as “at least one embodiment”. The terms such as “first”, “second”, and the like may refer to different objects or a same object, and are merely used to distinguish between specified objects, but do not imply a specific spatial order, a time order, an importance order, or the like of the specified objects. In some embodiments, a value, a process, a selected item, a determined item, a device, an apparatus, a means, a part, a component, or the like is referred to as “optimal”, “lowest”, “highest”, “minimum”, “maximum”, or the like. It should be understood that such a description is intended to indicate that a selection may be made among many available functional selections, and that such a selection does not need to be better, lower, higher, smaller, larger, or otherwise preferred than other selections in other aspects or in all aspects. As used in this specification, the term “determining” may cover a variety of actions. For example, “determining” may include operating, calculating, processing, exporting, investigating, looking up (for example, looking up in a table, a database, or another data structure), ascertaining, and the like. In addition, “determining” may include receiving (for example, receiving information), accessing (for example, accessing data in a memory), and the like. In addition, “determining” may include parsing, selecting, choosing, establishing, and the like.

The term “UI” used in this specification represents an interface for interaction and information exchange between a user and an application or an operating system, and implements a conversion between an internal form of information and a form acceptable to the user. For example, a UI of the application is source code written in a specific computer language such as Java or an extensible markup language (XML). The UI source code is parsed and rendered on an electronic device, and finally presented as user-recognizable content, for example, a UI element such as a picture, a text, or a button.

In some embodiments, an attribute and content of the UI element in the UI are defined by using a tag or a node. For example, a UI element included in the UI is specified in the XML by using nodes such as <Textview>, <ImgView>, and <VideoView>. One node corresponds to one UI element or one attribute in the UI. After being parsed and rendered, the node is presented as user-visible content. In addition, UIs of many applications such as a hybrid application (hybrid application) usually further include a web page. The web page may be understood as a special UI element embedded in a UI of an application. The web page is source code written in a specific computer language, for example, a hypertext markup language (HTML), cascading style sheets (CSS), or JavaScript (JS). The web page source code may be loaded and displayed as user-recognizable content by a browser or a web page display component that has a function similar to a function of a browser. Specific content included on the web page is also defined by using a tag or a node in the web page source code. For example, an element and an attribute of the web page are defined in the HTML by using <p>, <img>, <video>, or <canvas>. The term “UI element” used in this specification includes but is not limited to a visual UI element such as a window, a scrollbar, a table view, a button, a menu bar, a text box, a navigation bar, a toolbar, an image, a static text, or a widget.

In some embodiments, the UI element may further include a control. The control may be an encapsulation of data and methods. The control may have its own attributes and methods. The attributes are simple visitors of the control data, and the methods are some simple visible functions of the control. The control is a basic element of the user interface. For example, a control type may include but be not limited to a user interface control (a control used to develop and construct a user interface, for example, a control for an interface element such as a window, a text box, a button, or a drop-down menu), a chart control (a control used to develop a chart, to implement data visualization and the like), a report control (a control used to develop a report, to implement functions such as browsing, designing, editing, and printing of the report), a cell control (a control used to develop a cell (CELL), to implement data processing and operations in a grid), or the like. In embodiments of this disclosure, the control type may further include a composite control (which combines various existing controls to form a new control, and integrates performance of a plurality of controls), an extended control (which derives a new control based on an existing control, and adds new performance to the existing control or changes performance of the existing control), a customized control, or the like.

In some embodiments, the UI element may further include a page module. Based on a layout and an attribute of a control on a page, the page may be divided into a plurality of consecutive page modules. One page module may carry one or more of the following information types: a picture, a text, an operation button, a link, an animation, a sound, a video, and the like. One page module may be presented as a set of one or more controls, may be presented as a card, or may be presented as a set of cards and other controls. For example, the page module may be presented as an icon on a home page, a picture in a gallery, a card on a leftmost screen, or the like. In embodiments of this disclosure, different page modules may overlap or may not overlap. In embodiments of this disclosure, the page module may also be referred to as a module for short. The card may provide a service capability with a finer granularity than an application (APP), and directly present, to the user in an interactive card form, a service or content that the user is most concerned about. The card may be embedded in various apps or interaction scenarios, to better meet a user requirement. A plurality of elements of an application, such as a picture, a text, an operation button, and a link, are integrated into one card. The card may be associated with one or more user interfaces of the application. A user may perform an operation (for example, a tap operation) on the card, so that a display interface may jump to a user interface of a corresponding application. With the use of a card layout, different content can be displayed in a differentiated manner, so that content in a display interface is presented more intuitively, and the user may perform operations on different content more easily and accurately.

Some procedures described in embodiments of the present disclosure include a plurality of operations or steps that appear in a specific order. However, it should be understood that these operations or steps may not be performed or executed in parallel according to the order in which the operations or steps appear in embodiments of the present disclosure. Sequence numbers of the operations are merely used to distinguish between different operations, and the sequence numbers themselves do not represent any execution order. In addition, these procedures may include more or fewer operations, these operations or steps may be performed in sequence or executed in parallel, and these operations or steps may be combined.

In mobile operating systems such as Android and iOS, an animation is essentially to display a user interface UI or a UI element in real time based on a refresh rate. Due to a principle of human persistence of vision, it makes the user feel that a picture is in motion. The animation transforms from an initial state of the animation into a final state of the animation after animation time elapses. In this transformation process, the animation may be controlled by an animation type and an animation transformation form. For example, the animation type may include a displacement animation, a rotation animation, a scaling animation, a transparency animation, or the like. The animation transformation form can be controlled by a controller such as an interpolator and an evaluator. Such a controller may be configured to control a speed of transforming the animation in an animation time period.

However, conventionally, an animation is only a combination of simple animation effects. As a result, the animation effect is monotonous, which does not conform to a physical law, and does not consider a real usage scenario, a usage habit of a user, and the like. Therefore, embodiments of the present disclosure provide a new user interface display solution. Embodiments of the present disclosure relate to a new animation effect implementation solution, and provide a design and implementation of a magnetic force animation effect. Based on human factors research, a natural magnetic force effect is simulated to implement the magnetic force animation effect. In embodiments of the present disclosure, a magnetic force theory is used for the first time in the field of an animation effect of a UI framework, and a magnetic force feature animation effect is constructed. In embodiments of the present disclosure, a capability of constructing the “magnetic force” animation effect is mainly based on a natural magnetic force law. The “magnetic force” animation effect can humanize each control in the interface, allowing them to present a magnetic force attraction or repulsion scenario that is consistent with human life. A perfect presentation of the natural magnetic force theory in the field of the animation effect further proves an importance of human factors theory research, and also enables an electronic device with a screen to display a dynamic effect that conforms to a natural law. In a process of using the device by a user, this also better conforms to life experience, enhancing vitality and humanization of the device. Some illustrative embodiments of the present disclosure are described below with reference to the accompanying drawings.

### Example Device

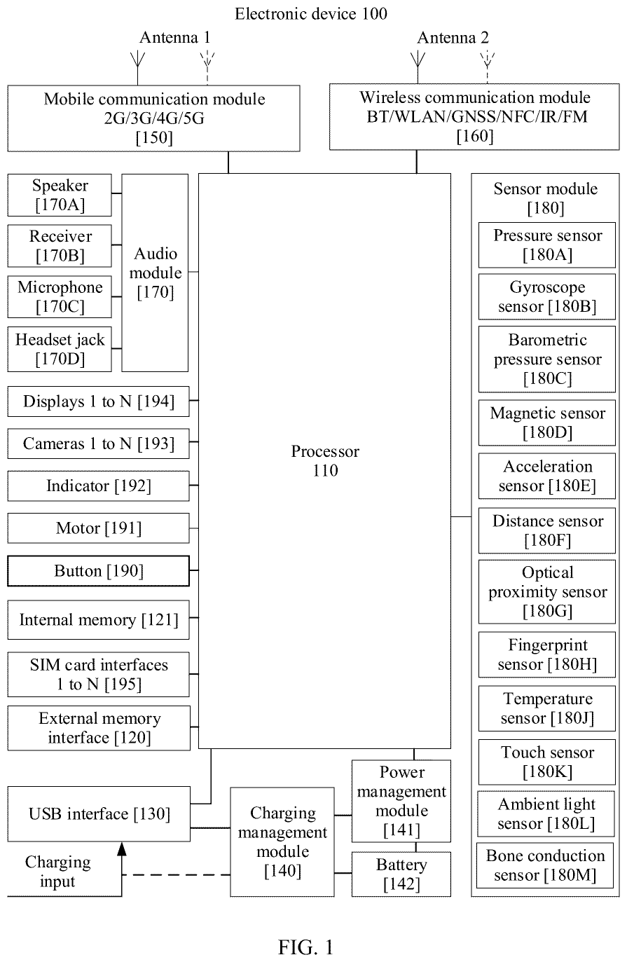

FIG. 1 is a schematic diagram of a hardware structure of an electronic device 100 that may implement an embodiment of the present disclosure. As shown in FIG. 1, the electronic device 100 may include a processor 110, an external memory interface 120, an internal memory 121, a universal serial bus (USB) interface 130, a charging management module 140, a power management module 141, a battery 142, an antenna 1, an antenna 2, a mobile communication module 150, a wireless communication module 160, an audio module 170, a speaker 170A, a receiver 170B, a microphone 170C, a headset jack 170D, a sensor module 180, a button 190, a motor 191, an indicator 192, a camera 193, a display 194, a subscriber identity module (SIM) card interface 195, and the like. The sensor module 180 may include a pressure sensor 180A, a gyroscope sensor 180B, a barometric pressure sensor 180C, a magnetic sensor 180D, an acceleration sensor 180E, a distance sensor 180F, an optical proximity sensor 180G, a fingerprint sensor 180H, a temperature sensor 180J, a touch sensor 180K, an ambient light sensor 180L, a bone conduction sensor 180M, and the like.

It should be understood that the structure shown in this embodiment of the present disclosure does not constitute a specific limitation on the electronic device 100. In some other embodiments of the present disclosure, the electronic device 100 may include more or fewer components than those shown in the figure, or some components may be combined, or some components may be split, or a different component arrangement may be used. The components shown in the figure may be implemented by hardware, software, or a combination of software and hardware.

The processor 110 may include one or more processing units. For example, the processor 110 may include an application processor (AP), a modem processor, a graphics processing unit (GPU), an image signal processor (ISP), a controller, a video codec, a digital signal processor (DSP), a baseband processor, a neural-network processing unit (NPU), and/or the like. Different processing units may be independent components, or may be integrated into one or more processors. The controller may generate an operation control signal based on instruction operation code and a time sequence signal, to complete control of instruction reading and instruction execution.

A memory may be further disposed in the processor 110, and is configured to store instructions and data. In some embodiments, the memory in the processor 110 is a cache memory. The memory may store instructions or data that has been used or is cyclically used by the processor 110. If the processor 110 needs to use the instructions or the data again, the processor may directly invoke the instructions or the data from the memory. This avoids repeated access, reduces waiting time of the processor 110, and improves system efficiency.

In some embodiments, the processor 110 may include one or more interfaces. The interface may include an inter-integrated circuit (I2C) interface, an inter-integrated circuit sound (12S) interface, a pulse code modulation (PCM) interface, a universal asynchronous receiver/transmitter (UART) interface, a mobile industry processor interface (MIPI), a general-purpose input/output (GPIO) interface, a subscriber identity module (SIM) interface, a universal serial bus (USB) interface, and/or the like.

The I2C interface is a bidirectional synchronization serial bus, and includes one serial data line (SDA) and one serial clock line (SCL). In some embodiments, the processor 110 may include a plurality of groups of I2C buses. The processor 110 may be separately coupled to the touch sensor 180K, a charger, a flashlight, the camera 193, and the like through different I2C bus interfaces. For example, the processor 110 may be coupled to the touch sensor 180K through the I2C interface, so that the processor 110 communicates with the touch sensor 180K through the I2C bus interface, to implement a touch function of the electronic device 100.

The I2S interface may be used for audio communication. In some embodiments, the processor 110 may include a plurality of groups of I2S buses. The processor 110 may be coupled to the audio module 170 through the I2S bus, to implement communication between the processor 110 and the audio module 170. In some embodiments, the audio module 170 may transmit an audio signal to the wireless communication module 160 through the I2S interface, to implement a function of answering a call through a Bluetooth headset.

The PCM interface may also be used for audio communication, and may perform sampling, quantizing, and encoding on an analog signal. In some embodiments, the audio module 170 and the wireless communication module 160 may be coupled through the PCM bus interface. In some embodiments, the audio module 170 may also transmit an audio signal to the wireless communication module 160 through the PCM interface, to implement a function of answering a call through a Bluetooth headset. Both the I2S interface and the PCM interface may be used for audio communication.

The UART interface is a universal serial data bus and used for asynchronous communication. The bus may be a bidirectional communication bus. It converts to-be-transmitted data between serial communication and parallel communication. In some embodiments, the UART interface is usually configured to connect to the processor 110 and the wireless communication module 160. For example, the processor 110 communicates with a Bluetooth module in the wireless communication module 160 through the UART interface, to implement a Bluetooth function. In some embodiments, the audio module 170 may transmit an audio signal to the wireless communication module 160 through the UART interface, to implement a function of playing music through a Bluetooth headset.

The MIPI interface may be configured to connect to the processor 110 and a peripheral component such as the display 194 or the camera 193. The MIPI interface includes a camera serial interface (CSI), a display serial interface (DSI), and the like. In some embodiments, the processor 110 communicates with the camera 193 through the CSI interface, to implement a photographing function of the electronic device 100. The processor 110 communicates with the display 194 through the DSI interface, to implement a display function of the electronic device 100.

The GPIO interface may be configured by software. The GPIO interface may be configured as a control signal or as a data signal. In some embodiments, the GPIO interface may be configured to connect the processor 110 to the camera 193, the display 194, the wireless communication module 160, the audio module 170, the sensor module 180, or the like. The GPIO interface may be further configured as an I2C interface, an I2S interface, a UART interface, a MIPI interface, or the like.

The USB interface 130 is an interface that conforms to USB standard specifications, and may be specifically a mini USB interface, a micro USB interface, a USB type-C interface, or the like. The USB interface 130 may be configured to connect to the charger to charge the electronic device 100, or may be configured to transmit data between the electronic device 100 and a peripheral device, or may be configured to connect to a headset, to play audio by using the headset. The interface may further be configured to connect to another electronic device such as an AR device.

It may be understood that an interface connection relationship between the modules illustrated in this embodiment of the present disclosure is merely an example for description, and does not constitute a limitation on the structure of the electronic device 100. In some other embodiments of the present disclosure, the electronic device 100 may alternatively use an interface connection different from that in the foregoing embodiment, or a combination of a plurality of interface connections.

The charging management module 140 is configured to receive a charging input from the charger. The charger may be a wireless charger or a wired charger. In some embodiments of wired charging, the charging management module 140 may receive a charging input of the wired charger through the USB interface 130. In some embodiments of wireless charging, the charging management module 140 may receive a wireless charging input through a wireless charging coil of the electronic device 100. The charging management module 140 may further supply power to the electronic device 100 through the power management module 141 while charging the battery 142.

The power management module 141 is configured to connect to the battery 142, the charging management module 140, and the processor 110. The power management module 141 receives an input from the battery 142 and/or the charging management module 140, and supplies power to the processor 110, the internal memory 121, the display 194, the camera 193, the wireless communication module 160, and the like. The power management module 141 may further be configured to monitor parameters such as a battery capacity, a battery cycle count, and a battery health status (electricity leakage or impedance). In some other embodiments, the power management module 141 may alternatively be disposed in the processor 110. In some other embodiments, the power management module 141 and the charging management module 140 may alternatively be disposed in a same component.

A wireless communication function of the electronic device 100 may be implemented by using the antenna 1, the antenna 2, the mobile communication module 150, the wireless communication module 160, the modem processor, the baseband processor, and the like. The antenna 1 and the antenna 2 are configured to transmit and receive an electromagnetic wave signal. Each antenna in the electronic device 100 may be configured to cover one or more communication frequency bands. Different antennas may be further multiplexed to improve antenna utilization. For example, the antenna 1 may be multiplexed as a diversity antenna in a wireless local area network. In some other embodiments, the antenna may be used in combination with a tuning switch.

The mobile communication module 150 may provide a solution that includes wireless communication such as 2G/3G/4G/5G and that is applied to the electronic device 100. The mobile communication module 150 may include at least one filter, a switch, a power amplifier, a low noise amplifier (LNA), and the like. The mobile communication module 150 may receive an electromagnetic wave through the antenna 1, perform processing such as filtering and amplification on the received electromagnetic wave, and transmit the electromagnetic wave to the modem processor for demodulation. The mobile communication module 150 may further amplify a signal modulated by the modem processor, and convert the signal into an electromagnetic wave for radiation through the antenna 1. In some embodiments, at least some functional modules of the mobile communication module 150 may be disposed in the processor 110. In some embodiments, at least some functional modules in the mobile communication module 150 may be disposed in a same device as at least some modules in the processor 110.

The modem processor may include a modulator and a demodulator. The modulator is configured to modulate a to-be-sent low-frequency baseband signal into a medium-high frequency signal. The demodulator is configured to demodulate a received electromagnetic wave signal into a low-frequency baseband signal. Then, the demodulator transmits the low-frequency baseband signal obtained through demodulation to the baseband processor for processing. The low-frequency baseband signal is processed by the baseband processor and then transmitted to the application processor. The application processor outputs a sound signal through an audio device (which is not limited to the speaker 170A, the receiver 170B, and the like), or displays an image or a video through the display 194. In some embodiments, the modem processor may be an independent component. In some other embodiments, the modem processor may be independent of the processor 110, and is disposed in a same device as the mobile communication module 150 or another functional module.

The wireless communication module 160 may provide a wireless communication solution that is applied to the electronic device 100 and that includes a wireless local area network (WLAN) (for example, a wireless fidelity (Wi-Fi) network), Bluetooth (BT), a global navigation satellite system (GNSS), frequency modulation (FM), a near field communication (NFC) technology, an infrared (IR) technology, or the like. The wireless communication module 160 may be one or more components integrating at least one communication processing module. The wireless communication module 160 receives an electromagnetic wave through the antenna 2, performs frequency modulation and filtering processing on an electromagnetic wave signal, and sends a processed signal to the processor 110. The wireless communication module 160 may further receive a to-be-sent signal from the processor 110, perform frequency modulation and amplification on the signal, and convert the signal into an electromagnetic wave for radiation through the antenna 2.

The electronic device 100 implements a display function by using the GPU, the display 194, the application processor, and the like. The GPU is a microprocessor for image processing, and is connected to the display 194 and the application processor. The GPU is configured to perform mathematical and geometric calculation, and render an image. The processor 110 may include one or more GPUs that execute program instructions to generate or change display information.

The display 194 is configured to display an image, a video, and the like. The display 194 includes a display panel. In some embodiments, the electronic device 100 may include one or N displays 194, where N is a positive integer greater than 1.

The electronic device 100 may implement a photographing function through the ISP, the camera 193, the video codec, the GPU, the display 194, the application processor, and the like.

The ISP is configured to process data fed back by the camera 193. For example, during photographing, a shutter is opened, and light is transmitted to a photosensitive element of the camera through a lens. An optical signal is converted into an electrical signal, and the photosensitive element of the camera transmits the electrical signal to the ISP for processing, to convert the electrical signal into a visible image. The ISP may further perform algorithm optimization on image noise, brightness, and a skin tone. The ISP may further optimize parameters such as exposure and a color temperature in a photographing scenario. In some embodiments, the ISP may be disposed in the camera 193.

The camera 193 is configured to capture a static image or a video. An optical image of an object is generated through the lens, and is projected onto the photosensitive element. The photosensitive element converts an optical signal into an electrical signal, and then transmits the electrical signal to the ISP for converting the electrical signal into a digital image signal. The ISP outputs the digital image signal to the DSP for processing. The DSP converts the digital image signal into an image signal in a format such as standard RGB or YUV. In some embodiments, the electronic device 100 may include one or N cameras 193, where N is a positive integer greater than 1.

The digital signal processor is configured to process a digital signal, and may process another digital signal in addition to the digital image signal. For example, when the electronic device 100 selects a frequency, the digital signal processor is configured to perform Fourier transform and the like on frequency energy.

The video codec is configured to compress or decompress a digital video. The electronic device 100 may support one or more types of video codecs. In this way, the electronic device 100 may play or record videos in a plurality of coding formats, for example, moving picture experts group (MPEG)-1, MPEG-2, MPEG-3, and MPEG-4.

The NPU is a neural-network (NN) computing processor, and quickly processes input information based on a structure of a biological neural network, for example, based on a transfer mode between human brain neurons, and may further continuously perform self-learning. The NPU may implement applications such as intelligent cognition of the electronic device 100, for example, image recognition, facial recognition, voice recognition, and text understanding.

The external memory interface 120 may be configured to connect to an external storage card, for example, a micro SD card, to extend a storage capability of the electronic device 100. The external memory card communicates with the processor 110 through the external memory interface 120, to implement a data storage function. For example, files such as music and a video are stored in the external storage card.

The internal memory 121 may be configured to store computer-executable program code. The executable program code includes instructions. The internal memory 121 may include a program storage area and a data storage area. The program storage area may store an operating system, an application required for at least one function (such as a sound playing function and an image playing function), and the like. The data storage area may store data (for example, audio data and a phone book) and the like created during usage of the electronic device 100. In addition, the internal memory 121 may include a high-speed random access memory, and may further include a non-volatile memory, for example, at least one magnetic disk storage device, a flash storage device, and a universal flash storage (UFS). The processor 110 runs the instructions stored in the internal memory 121 and/or the instructions stored in the memory disposed in the processor, to execute various function applications of the electronic device 100 and data processing.

The electronic device 100 may implement an audio function such as music playing and recording through the audio module 170, the speaker 170A, the receiver 170B, the microphone 170C, the headset jack 170D, the application processor, and the like.

The SIM card interface 195 is configured to connect to a SIM card. The SIM card may be inserted into the SIM card interface 195 or removed from the SIM card interface 195, to implement contact with or separation from the electronic device 100.

A software system of the electronic device 100 may use a layered architecture, an event-driven architecture, a microkernel architecture, a microservice architecture, or a cloud architecture. In embodiments of the present disclosure, a mobile operating system of a layered architecture is used as an example to describe a software structure of the electronic device 100.

### “Magnetic Force” Animation Effect

### Example 1

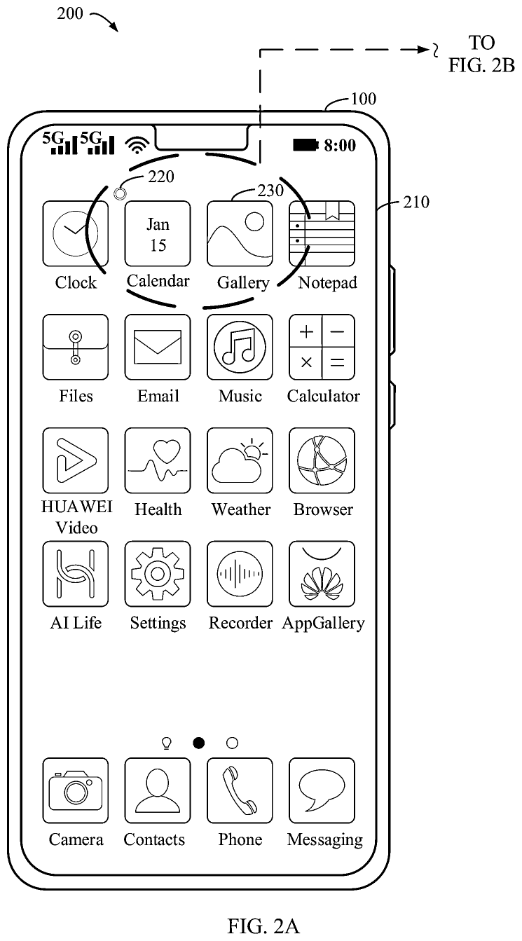

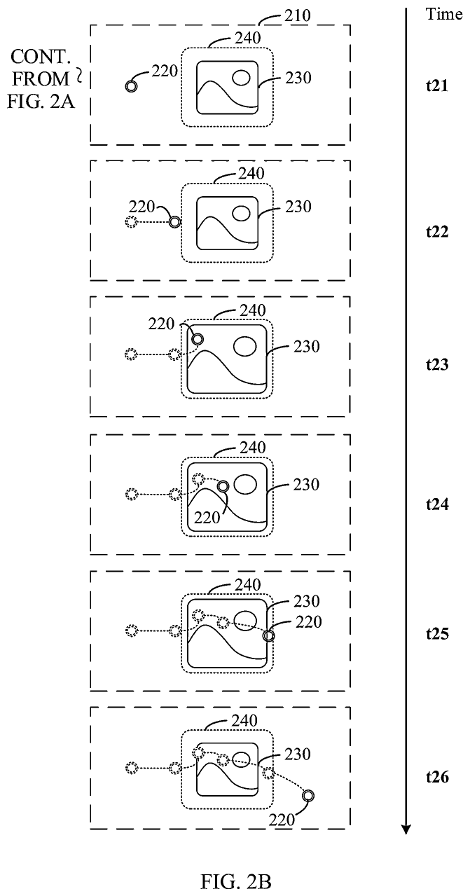

The following describes a display process of a user interface according to some embodiments of the present disclosure with reference to FIG. 2A and FIG. 2B. FIG. 2A and FIG. 2B are a schematic diagram 200 of a change of a user interface according to some embodiments of the present disclosure.

As shown in FIG. 2A, the electronic device 100 may provide a user interface 210 through a display (for example, the display 194). In some embodiments, as shown in FIG. 2A, the electronic device 100 may include, for example, a smartphone. The user interface 210 may be, for example, a desktop interface of the smartphone. It should be understood that a specific form of the electronic device in FIG. 2A is only an example, and the electronic device may alternatively include another appropriate type of a device with a screen, and the user interface 210 may alternatively include another appropriate user interface.

In some embodiments, as shown in FIG. 2A, the user interface 210 may include a cursor 220 and a plurality of icons 230. It should be understood that the cursor 220 may further be presented as another appropriate pointing element, which presents a location of a current interaction of a user. In some embodiments, the electronic device 100 may determine a location of the cursor 220, for example, by using a pointing device (for example, a mouse or a touchpad) connected to the electronic device 100. Optionally, the electronic device 100 may determine a location of the cursor 220, for example, by detecting a hovering location of a writing entity (for example, a stylus, or a finger of the user) on the display 194. Optionally, the electronic device 100 may determine a location of the cursor 220 by using another appropriate technology (for example, determining a visual focus of the user and the like).

FIG. 2B further shows changes of the user interface 210 at different moments due to a motion of the cursor 220. To more clearly describe an animation effect initiated by the cursor 220, FIG. 2B further retains only the cursor 220 and the icon 230 (for example, an icon of a Gallery application) in a view on a right side, and does not display other UI elements in the user interface 210.

As shown in FIG. 2B, at a moment t21, the cursor 220 is located outside a “magnetic force” range 240 (also referred to as a target range) of the icon 230. In some embodiments, the “magnetic force” range 240 represents an effective range that produces a “magnetic force” animation effect on the icon 230 or due to the icon 230.

In some embodiments, the “magnetic force” range 240 may be determined based on a size of the icon 230. For example, the “magnetic force” range 240 may correspond to a boundary of the icon 230. Optionally, the “magnetic force” range 240 may extend outward a predetermined distance from a boundary. Optionally, the “magnetic force” range 240 may be determined based on a central location of the icon 230, and a size of the “magnetic force” range 240 may be, for example, greater than, equal to, or less than the size of the icon 230. In some embodiments, the predetermined distance may be, for example, a parameter that can be configured by a developer or a user.

In some embodiments, the “magnetic force” range 240 may also be determined, for example, based on a central location of the icon 230. For example, the “magnetic force” range 240 may be a predetermined range from the central location of the icon 230. For example, the predetermined range may also be a parameter that can be configured by a developer or a user.

In some embodiments, the “magnetic force” range 240 may alternatively be determined based on a “magnetic force” propagation distance of the cursor 220 that is about to interact with the “magnetic force” range 240. For example, the “magnetic force” range 240 may be a range that is from the central location of the icon 230 and that does not exceed the “magnetic force” propagation distance.

As shown in FIG. 2B, at a moment t22, in response to an operation performed by the user on the cursor 220, the cursor 220 moves to a boundary of the “magnetic force” range 240, and is about to enter the “magnetic force” range 240. Further, from the moment t22 to a moment t23, in response to the motion in which the cursor 220 enters the “magnetic force” range 240, the icon 230 may produce a “magnetic force” animation effect. In some embodiments, the electronic device 100 may determine, based on a comparison between the target range 240 and location information that is associated with the cursor 220, that the cursor 220 enters (or leaves) the target range 240. For example, the location information may indicate a central location or a boundary location of the cursor 220.

In some embodiments, as shown in FIG. 2B, the “magnetic force” animation effect may enable the size of the icon 230 to be increased. It is considered that, in a natural world, in a case in which magnetic induction intensity is constant, a “magnetic force” magnitude depends on a surface area of a magnetic pole. For the user interface, the surface area of the magnetic pole may be represented as a size of a UI element. In some embodiments, a degree (also referred to as a “change degree”) to which the icon 230 is enlarged due to the “magnetic force” animation effect may be determined, for example, based on a size of the cursor 220 and/or the size of the icon 230.

In addition, in the natural world, the “magnetic force” magnitude is also associated with a magnetic attraction distance between the magnetic pole and a target object. For the user interface, the magnetic attraction distance may be represented as a distance between two UI elements. In some embodiments, the degree (also referred to as the “change degree”) to which the icon 230 is enlarged due to the “magnetic force” animation effect may be determined, for example, based on a distance between the cursor 220 and the icon 230. The distance may, for example, indicate a distance between the cursor 220 and the central location of the icon 230 when the cursor 220 enters the “magnetic force” range 240.

In addition, to be closer to real interaction experience in nature, in some embodiments, the degree (also referred to as the “change degree”) to which the icon 230 is enlarged due to the “magnetic force” animation effect may be determined, for example, based on a motion speed of the cursor 220. For example, the motion speed may be an instantaneous speed at which the cursor 220 enters the “magnetic force” range 240. Alternatively, the motion speed may be an average speed of the cursor 220 in a target time period, for example, an average speed in a predetermined time period before the cursor 220 enters the “magnetic force” range 240.

In some embodiments, the change degree (for example, the degree to which the size of the icon 230 is increased) of the “magnetic force” animation effect may be directly proportional to the size of the cursor 220 and/or the size of the icon 230, inversely proportional to the distance between the cursor 220 and the icon 230, and inversely proportional to the motion speed of the cursor 220. For example, the change degree may be represented as follows:

$$F = K * R / ( r * v ) \qquad ( 1 )$$

F represents a “magnetic force” magnitude, K represents a constant, R represents a size of the icon 230, r represents a distance between the cursor 220 and the icon 230, and v represents a motion speed of the cursor.

Still refer to FIG. 2B. At a moment t24, if the cursor 220 remains within the “magnetic force” range 240, the icon 230 may remain in an enlarged state. At a moment t25, the cursor 220 may continue to move to the boundary of the “magnetic force” range 240, and be about to leave the “magnetic force” range. At a moment t26, the icon 230 may be, for example, restored from the enlarged state to an initial state.

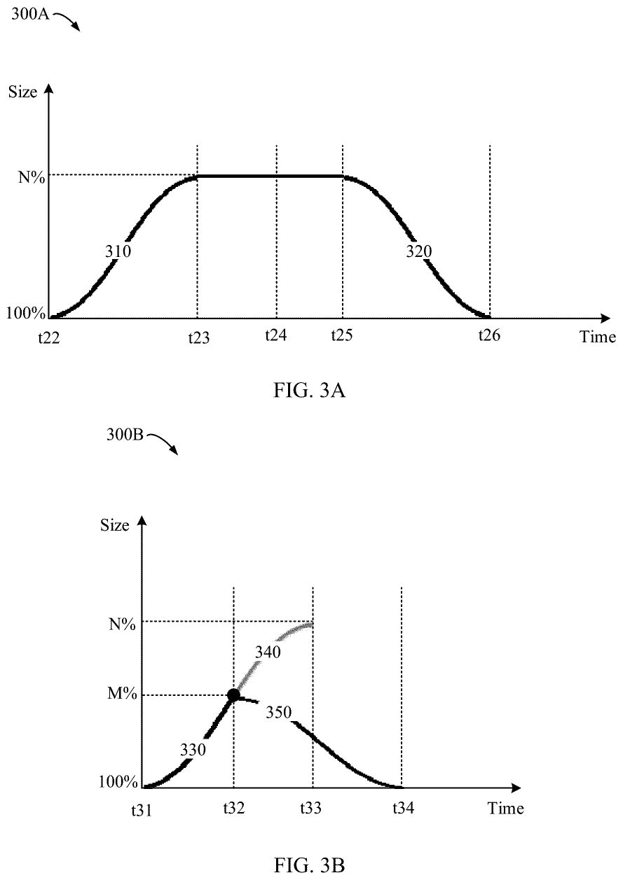

FIG. 3A further shows a schematic diagram 300A of a change trend of a UI element according to some embodiments of the present disclosure. As shown in FIG. 3A, in the schematic diagram 300A, a horizontal axis represents time, and a vertical axis represents a size of the icon 230. As shown in FIG. 3A, from the moment t22 to the moment t23, in response to the cursor 220 entering the “magnetic force” range 240, the icon 230 may be changed to N % of an original size based on a curve 310. From the moment t23 to the moment t25, the cursor 220 remains within the “magnetic force” range 240, and the icon 230 remains in the enlarged state, that is, N %. From the moment t25 to the moment t26, in response to the cursor 220 leaving the “magnetic force” range 240, the icon 230 may be restored to the original size based on a curve 320.

Based on the “magnetic force” animation effect manner discussed above, embodiments of the present disclosure can enable the electronic device with the screen to present a dynamic effect that conforms to a natural law.

In some embodiments, the “magnetic force” animation effect that the icon 230 is enlarged to N %, for example, has a predetermined animation effect duration. In some cases, the cursor 220 may have left the “magnetic force” range 240 before the animation effect is completed. Embodiments of the present disclosure further provide an interruption mechanism of the “magnetic force” animation effect. FIG. 3B further shows a schematic diagram 300B of a change trend of a UI element according to some embodiments of the present disclosure.

As shown in FIG. 3B, at a moment t31, in response to the cursor 220 entering the “magnetic force” range 240, the icon 230 may present, for example, a “magnetic force” animation effect of increasing a size based on a curve 330. A duration of the animation effect may be, for example, 250 ms. At a moment t32, the cursor 220, for example, has already left the “magnetic force” range 240 within 250 ms. In this case, the icon 230 may terminate the “magnetic force” animation effect of increasing the size, and start presenting, from the moment t32, an animation effect of restoring to an initial size based on a curve 350. That is, the icon 230 does not perform a continued enlargement process shown in a curve 340, but restores, shown in the curve 350, from M % to the initial size. For example, the animation effect of restoring to the initial size may, for example, have a fixed duration, without depending on a degree to which the icon 230 has been enlarged.

In this manner, embodiments of the present disclosure can provide the interruption mechanism related to the “magnetic force” effect, so that the user can obtain more rapid interaction feedback, to avoid that an animation effect produced by a previous interaction is still presented when the user quickly operates to a next state.

It should be understood that although a “magnetic force” animation effect process of the cursor 220 and the icon 230 is described above with reference to FIG. 2B, FIG. 3A, and FIG. 3B, the foregoing mechanism may also be applied to another appropriate UI element. In addition, the “magnetic force” animation effect in FIG. 2B represents an attraction effect, which enables the icon 230 to be enlarged. In some embodiments, the “magnetic force” animation effect, for example, may also enable a size of a UI element to be reduced, and present a “magnetic force” repulsion effect.

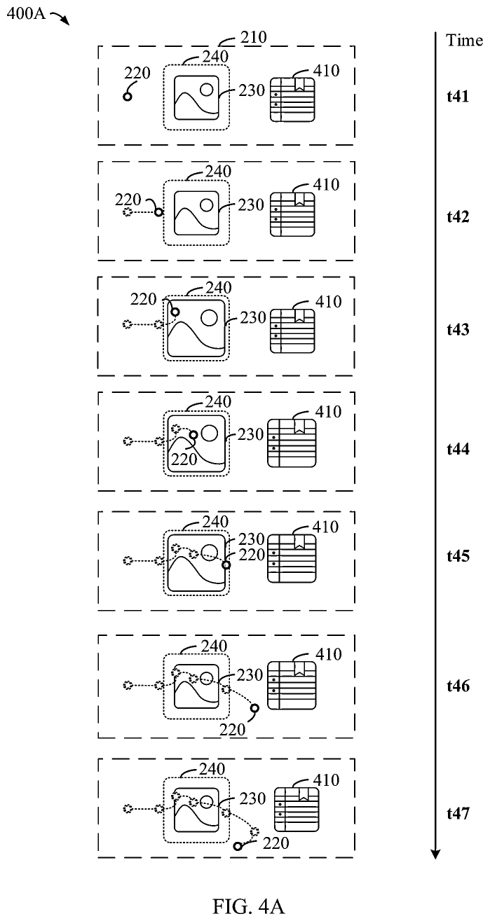

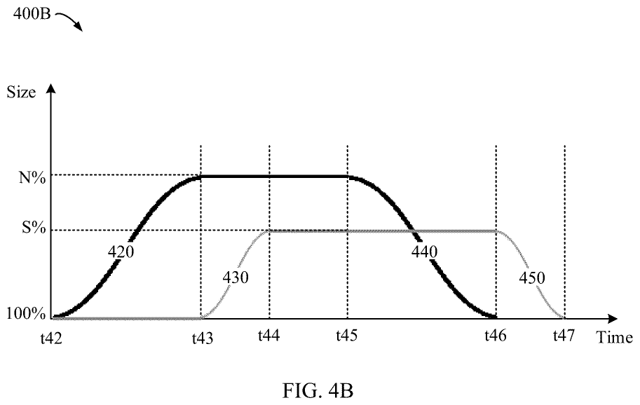

In some embodiments, the “magnetic force” may also be propagated to another UI element. FIG. 4A further shows a schematic diagram 400A of a change of a user interface according to some other embodiments of the present disclosure. An interaction process between the cursor 220 and the icon 230 is similar to the process discussed in FIG. 2B. A difference is that the cursor 220 further triggers a “magnetic force” animation effect of another icon 410.

Specifically, at a moment t41, the cursor 220 is located outside the “magnetic force” range 240, and both the icon 230 and the icon 410 (for example, an icon of a Notepad application) remain in an initial size. At a moment t42, the cursor 220 moves to enter the “magnetic force” range 240, and enables the icon 230 to be enlarged. In addition, the “magnetic force” animation effect is completed, for example, at a moment t43.

In some embodiments, at the moment t43 or a predetermined moment after the moment t42, a “magnetic force” animation effect of the icon 410 is correspondingly triggered. To reflect a “magnetic force” propagation effect, a trigger moment at which the icon 410 is enlarged may be later than the trigger moment t42 at which the icon 230 is enlarged. In some embodiments, a moment at which the “magnetic force” animation effect of the icon 410 is triggered may be determined based on a magnetic force propagation speed and a distance from the cursor 220 to the icon 410.

In some embodiments, a change degree of the “magnetic force” animation effect of the icon 410 may be determined based on a size of the cursor 220 and/or a size of the icon 410, a distance between the cursor 220 and the icon 410, and/or a speed of the icon 220. For example, because the icon 410 and the icon 230 have a same size, and a distance between the icon 410 and the cursor 210 is greater than that between the icon 230 and the cursor 210, an enlarged degree of the icon 410 may be, for example, less than an enlarged degree of the icon 230.

At a moment t44, the icon 410, for example, may be enlarged based on the “magnetic force” animation effect. At a moment t45, the cursor 220 moves out of the “magnetic force” range 240, and triggers the icon 230 to restore to the initial size. At a moment t46, the icon 230 is restored to the initial size. In some embodiments, the icon 410 may be triggered to restore to the initial size after a predetermined delay (for example, at the moment t46) after the moment t46. At a moment t47, the icon 410 is restored to the initial size.

FIG. 4B further shows a schematic diagram 400B of a change trend of a UI element according to some embodiments of the present disclosure. As shown in FIG. 4B, in the schematic diagram 400B, a horizontal axis represents time, and a vertical axis represents a size of the icon 230. As shown in FIG. 4B, from the moment t42 to the moment t43, in response to the cursor 220 entering the “magnetic force” range 240, the icon 230 may change to N % of the original size based on a curve 420. At the moment t44 after the moment t42, the icon 410 is enlarged to S % of the original size based on a curve 430, where S<N. From the moment t43 to the moment t45, the cursor 220 remains within the “magnetic force” range 240, and the icon 230 remains in the enlarged state, that is, N %. From the moment t45 to the moment t46, in response to the cursor 220 leaving the “magnetic force” range 240, the icon 230 may be restored to the original size based on a curve 440. Further, from the moment t46 to the moment t47, the icon 410 is restored to the original size based on a curve 450.

Based on such a manner, embodiments of the present disclosure may further simulate an animation effect of “magnetic force” propagation in a natural world, thereby further improving a sense of reality of an interaction.

In some embodiments, the electronic device 100 correspondingly presents a “magnetic force” animation effect based on an interaction location indicated by a user interaction, and does not present a UI element, for example, a cursor, corresponding to the interaction location.

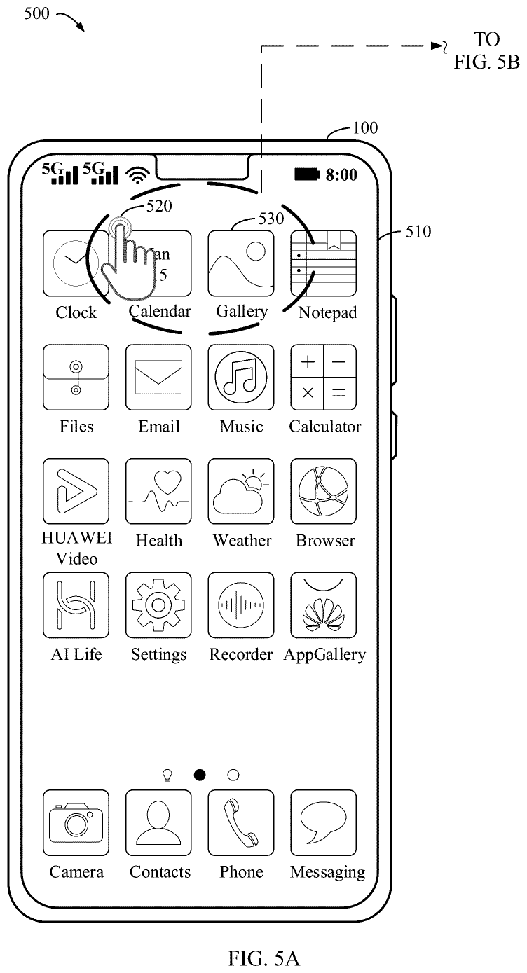

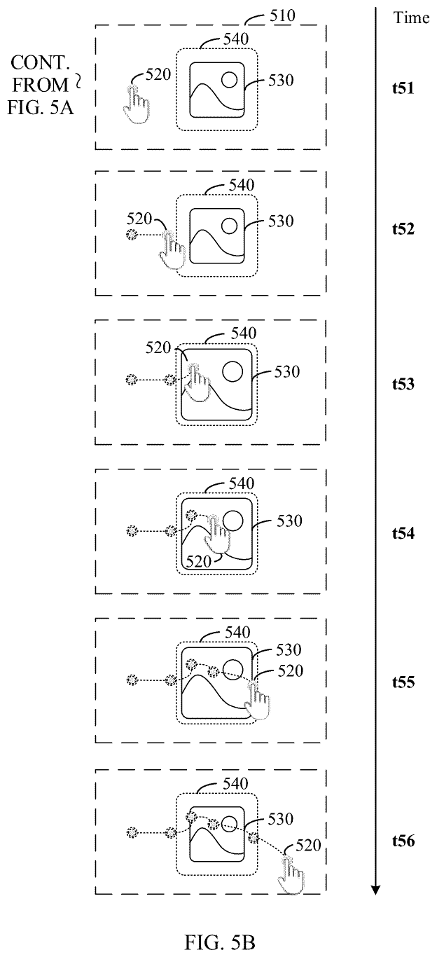

FIG. 5A and FIG. 5B are a schematic diagram 500 of a change of a user interface according to some embodiments of the present disclosure. As shown in FIG. 5A, the electronic device 100 may provide a user interface 510 through a display (for example, the display 194). In some embodiments, as shown in FIG. 5A, the electronic device 100 may include, for example, a smartphone. The user interface 510 may be, for example, a desktop interface of the smartphone. It should be understood that a specific form of the electronic device in FIG. 5A is only an example, and the electronic device may alternatively include another appropriate type of a device with a screen, and the user interface 510 may alternatively include another appropriate user interface.

In some embodiments, as shown in FIG. 5A, the user interface 510 may include a plurality of icons 530. In some embodiments, the electronic device 100 may further detect an interaction location 520 indicated by a user interaction. In some embodiments, the electronic device 100 may determine the interaction location 520, for example, by using a pointing device (for example, a mouse or a touchpad) connected to the electronic device 100. Optionally, the electronic device 100 may determine the interaction location 520, for example, by detecting a hovering location of a writing entity (for example, a stylus or a finger of the user) on the display 194. Optionally, the electronic device 100 may determine the interaction location 520 by using another appropriate technology (for example, determining a visual focus of the user and the like). It should be understood that, different from the example shown in FIG. 2A, the electronic device 100 may not present a UI element, for example, a cursor, corresponding to the interaction location 520.

Similar to the interface interaction process shown in FIG. 2B, as shown in FIG. 5B, at a moment t51, the interaction location 520 is located outside a “magnetic force” range 540 of the icon 530, and the icon 530 may be in a normal display state. At t52, the interaction location 520, for example, moves to a boundary of the “magnetic force” range 540, and triggers the icon 530 to produce a “magnetic force” animation effect. Specifically, the “magnetic force” animation effect, for example, may enable a size the icon 530 to be increased to a predetermined multiple. In some embodiments, the predetermined multiple may be similarly determined, for example, with reference to Formula (1) discussed above. That is, the predetermined multiple may be determined based on speed information of the user interaction, the size of the icon 530, and a distance between the interaction location and the icon 530.

As shown in FIG. 5B, at a moment t53, the icon 530 is enlarged to the predetermined multiple based on the “magnetic force” animation effect. It should be understood that an enlargement process of the icon 530 may be a time-varying curve based on the size discussed above. For example, the following describes a Bézier curve or an elastic force curve in detail. Still refer to FIG. 5B. At a moment t54, when the interaction location 520 remains within the “magnetic force” range 540, the icon 530 may remain in an enlarged state.

At a moment t55, the interaction location 520 may move to the boundary of the “magnetic force” range 540, and trigger the icon 530 to restore to a normal display state. For example, a reduction process of the icon 530 may also be a time-varying curve based on the size discussed above. For example, the following describes the Bézier curve or the elastic force curve in detail. At a moment t56, the interaction location 520 moves out of the “magnetic force” range 540, and the icon 530 has been restored to the normal display state.

Based on such a manner, in embodiments of the present disclosure, the “magnetic force” animation effect may be introduced in more diversified interaction scenarios, thereby further improving a sense of reality of an interaction.

### Example 2

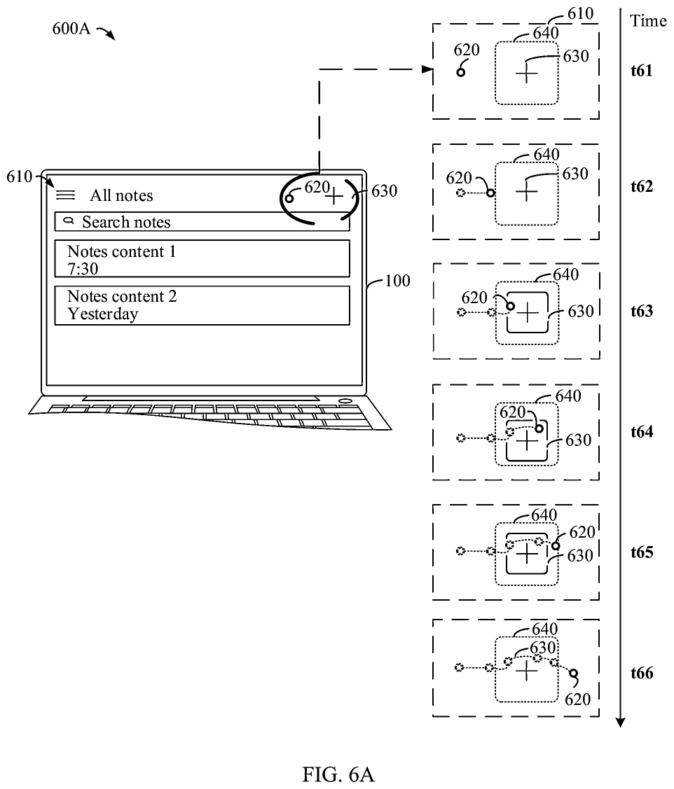

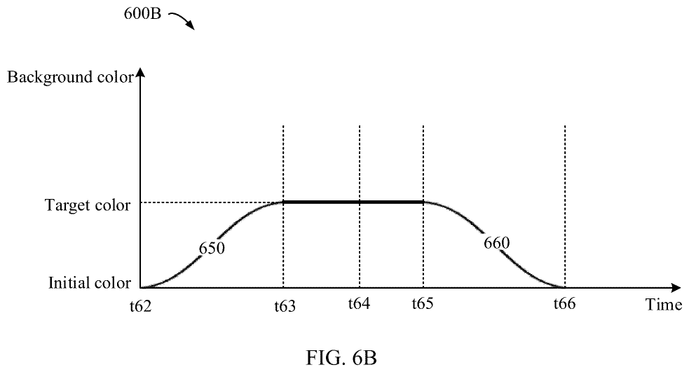

The following describes a display process of a user interface according to some other embodiments of the present disclosure with reference to FIG. 6A and FIG. 6B. FIG. 6A is a schematic diagram 600A of a change of a user interface according to some embodiments of the present disclosure.

As shown in FIG. 6A, the electronic device 100 may provide a user interface 610 through a display (for example, the display 194). In some embodiments, as shown in FIG. 6A, the electronic device 100 may include, for example, a notebook computer. The user interface 610 may be, for example, an interface of an application that is run in the notebook computer. It should be understood that a specific form of the electronic device in FIG. 6A is only an example, and the electronic device may alternatively include another appropriate type of a device with a screen, and the user interface 610 may alternatively include another appropriate user interface.

In some embodiments, as shown in FIG. 6A, the user interface 610 may include a cursor 620 and a control 630. It should be understood that the cursor 620 may further be presented as another appropriate pointing element, which presents a location of a current interaction of a user. In some embodiments, the electronic device 100 may determine a location of the cursor 620, for example, by using a pointing device (for example, a mouse or a touchpad) connected to the electronic device 100. Optionally, the electronic device 100 may determine a location of the cursor 620, for example, by detecting a hovering location of a writing entity (for example, a stylus, or a finger of the user) on the display 194. Optionally, the electronic device 100 may determine a location of the cursor 620 by using another appropriate technology (for example, determining a visual focus of the user and the like).

FIG. 6A further shows a change of the user interface 610 due to a motion of the cursor 620 at different moments. To more clearly describe an animation effect initiated by the cursor 620, FIG. 6A further retains only the cursor 620 and the control 630 (for example, a control used for adding a notepad) in a view on a right side, and does not display other UI elements in the user interface 610.

As shown in FIG. 6A, at a moment t61, the cursor 620 is located outside a “magnetic force” range 640 (also referred to as a target range) of an icon 630. In some embodiments, the “magnetic force” range 640 represents an effective range that produces a “magnetic force” animation effect on the control 630 or due to the control 630. For a process of determining the “magnetic force” range 640, refer to the process of determining the “magnetic force” range 240 described above in FIG. 2B. Details are not described herein again.

As shown in FIG. 6A, at a moment t62, in response to an operation performed the user on the cursor 620, the cursor 620 moves to a boundary of the “magnetic force” range 640, and is about to enter the “magnetic force” range 640. Further, from the moment t62 to a moment t63, in response to the motion in which the cursor 620 enters the “magnetic force” range 640, the icon 630 may produce a “magnetic force” animation effect. For example, as shown in FIG. 6B, the “magnetic force” animation effect may be to enable a background board color of the control 630 to be changed, for example, changed from an initial color to a target color. Alternatively or additionally, a size of a middle graphic part of the icon 630 may also change, for example, be increased.

In some embodiments, a change degree (for example, a change degree of the background board color of the control 630 may be, for example, quantized based on a difference between an RGB value of the initial color and an RGB value of the target color) of the “magnetic force” animation effect may be directly proportional to a size of the cursor 620 and/or a size of the control 630, inversely proportional to a distance between the cursor 620 and the control 630, and inversely proportional to a motion speed of the cursor 620. In some embodiments, the change degree of the “magnetic force” animation effect may be similarly determined with reference to Formula (1).

Still refer to FIG. 6A. At a moment t64, if the cursor 620 remains within the “magnetic force” range 640, the background board color of the control 630 may remain in the target color. At a moment t65, the cursor 620 may continue to move to the boundary of the “magnetic force” range 640, and be about to leave the “magnetic force” range. At a moment t66, the control 630 may be, for example, restored to an initial state. That is, the background board color is restored to the initial color.

FIG. 6B further shows a schematic diagram 600B of a change trend of a UI element according to some embodiments of the present disclosure. As shown in FIG. 6B, in the schematic diagram 600B, a horizontal axis represents time, and a vertical axis represents a background board color of the control 630, that is, a background color. As shown in FIG. 6B, from the moment t62 to the moment t63, in response to the cursor 620 entering the “magnetic force” range 640, the control 630 may change from the initial color to the target color based on a curve 650. From the moment t63 to the moment t65, the cursor 620 remains within the “magnetic force” range 640, and the background board of the control 630 consistently remains in the target color. From the moment t65 to the moment t66, in response to the cursor 620 leaving the “magnetic force” range 640, the background board of the control 630 may be restored to the initial color based on a curve 660.

Based on the “magnetic force” animation effect manner discussed above, embodiments of the present disclosure can enable the electronic device with the screen to present a dynamic effect that conforms to a natural law.

### Example 3

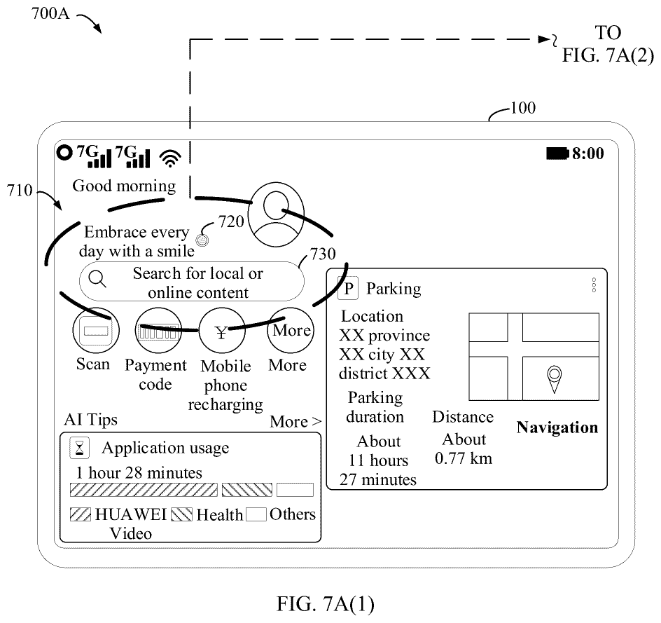

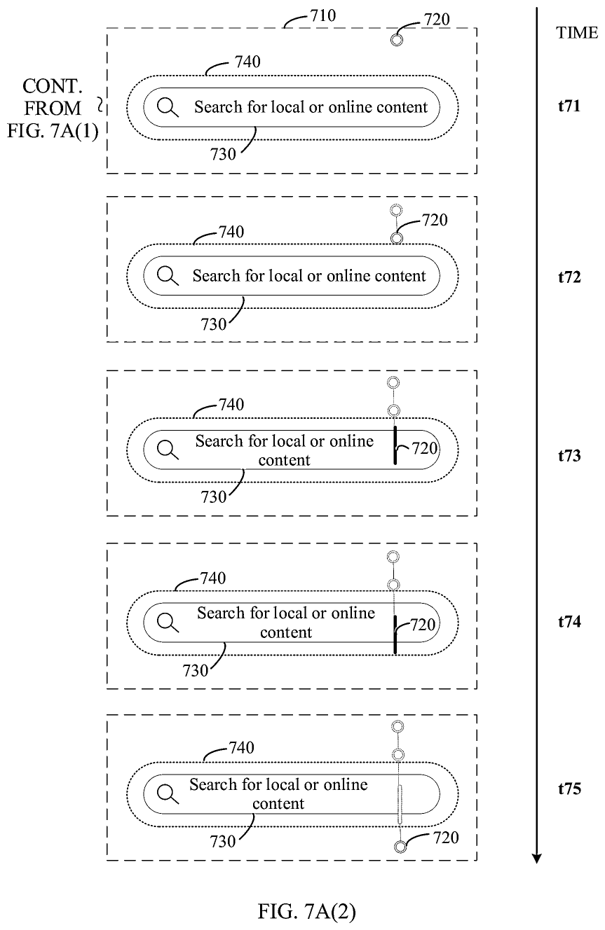

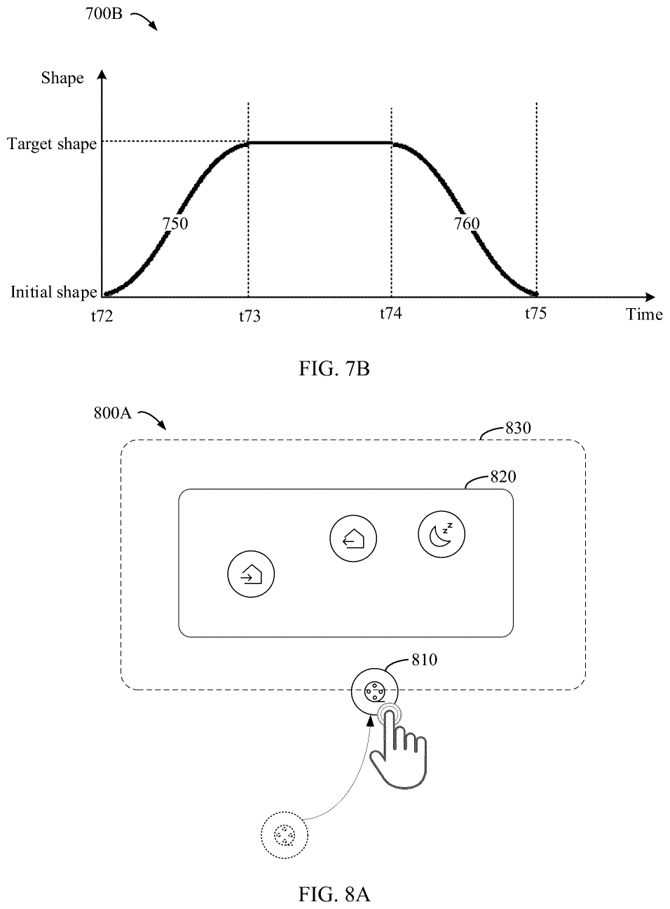

The following describes a display process of a user interface according to some other embodiments of the present disclosure with reference to FIG. 7A(1), FIG. 7A(2), and FIG. 7B. FIG. 7A(1) and FIG. 7A(2) are a schematic diagram 700A of a change of a user interface according to some embodiments of the present disclosure.

As shown in FIG. 7A(1), the electronic device 100 may provide a user interface 710 through a display (for example, the display 194). In some embodiments, as shown in FIG. 7A(1), the electronic device 100 may include, for example, a tablet computer. The user interface 710 may be, for example, a leftmost screen interface of the tablet computer. It should be understood that a specific form of the electronic device in FIG. 7A(1) is only an example, and the electronic device may alternatively include another appropriate type of a device with a screen, and the user interface 710 may alternatively include another appropriate user interface.

In some embodiments, as shown in FIG. 7A(1), the user interface 710 may include a cursor 720 and a control 730. It should be understood that the cursor 720 may further be presented as another appropriate pointing (pointing) element, which presents a location of a current interaction of a user. In some embodiments, the electronic device 100 may determine a location of the cursor 720, for example, by using a pointing device (for example, a mouse or a touchpad) connected to the electronic device 100. Optionally, the electronic device 100 may determine a location of the cursor 720, for example, by detecting a hovering location of a writing entity (for example, a stylus, or a finger of the user) on the display 194. Optionally, the electronic device 100 may determine a location of the cursor 720 by using another appropriate technology (for example, determining a visual focus of the user and the like).

FIG. 7A(2) further shows a change of the user interface 710 due to a motion of the cursor 720 at different moments. To more clearly describe an animation effect initiated by the cursor 720, FIG. 7A(2) further retains only the cursor 720 and the control 730 (for example, a search control used for searching content) in a view on a right side, and does not display other UI elements in the user interface 710.

As shown in FIG. 7A(2), at a moment t71, the cursor 720 is located outside a “magnetic force” range 740 (also referred to as a target range) of an icon 730. In some embodiments, the “magnetic force” range 740 represents an effective range that produces a “magnetic force” animation effect on the control 730 or due to the control 730. For a process of determining the “magnetic force” range 740, refer to the process of determining the “magnetic force” range 240 described above in FIG. 2B. Details are not described herein again.

As shown in FIG. 7(2), at a moment t72, in response to an operation performed by the user on the cursor 720, the cursor 720 moves to a boundary of the “magnetic force” range 740, and is about to enter the “magnetic force” range 740. Further, from the moment t72 to a moment t73, in response to the motion in which the cursor 720 enters the “magnetic force” range 740, the cursor 720 may produce a “magnetic force” animation effect. For example, as shown in FIG. 7(2), the “magnetic force” animation effect may be to enable a shape of the cursor 720 to be changed, for example, changed from a circular cursor to a vertical cursor. Alternatively or additionally, the “magnetic force” animation effect may include enabling a color or transparency of the cursor 720 to be changed correspondingly.

In some embodiments, a change degree (for example, a degree to which the shape of the cursor 720 is changed) of the “magnetic force” animation effect may be directly proportional to a size of the cursor 720 and/or a size of the control 730, may be inversely proportional to a distance between the cursor 720 and the control 730, and inversely proportional to a motion speed of the cursor 720. In some embodiments, the change degree of the “magnetic force” animation effect may be similarly determined with reference to Formula (1).

Still refer to FIG. 7A(2). If the cursor 720 remains within the “magnetic force” range 740, the control 720 may remain in a vertical cursor form. At a moment t74, the cursor 720 may continue to move to the boundary of the “magnetic force” range 740, and be about to leave the “magnetic force” range. At a moment t75, the cursor 720 may be, for example, restored to an initial state, that is, restored to a circular cursor form.

FIG. 7B further shows a schematic diagram 700B of a change trend of a UI element according to some embodiments of the present disclosure. As shown in FIG. 7B, in the schematic diagram 700B, a horizontal axis represents time, and a vertical axis represents a shape of the cursor 720. As shown in FIG. 7B, from the moment t72 to the moment t73, in response to the cursor 720 entering the “magnetic force” range 740, the cursor 720 may be transformed from an initial shape to a target shape based on a curve 750. From the moment t73 to the moment t74, the cursor 720 remains within the “magnetic force” range 740, and a background board of the control 730 consistently remains in a target color. From the moment t74 to the moment t75, in response to the cursor 720 leaving the “magnetic force” range 740, the cursor 720 may be restored to the initial shape based on a curve 760.

Based on the “magnetic force” animation effect manner discussed above, embodiments of the present disclosure can enable the electronic device with the screen to present a dynamic effect that conforms to a natural law.

### Example 4

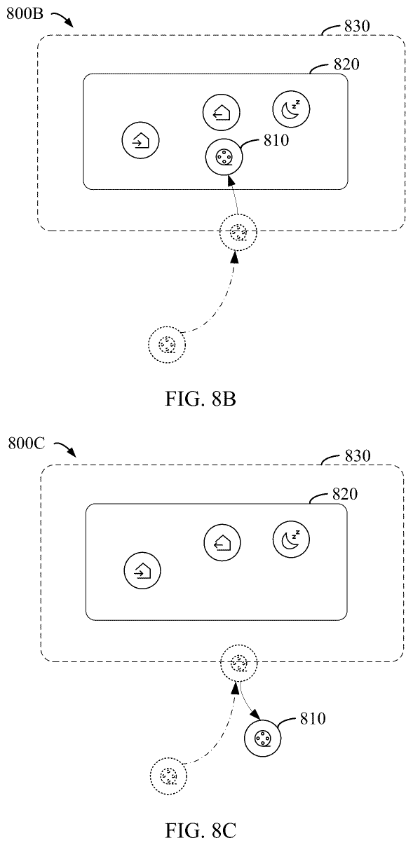

The following describes a display process of a user interface according to some other embodiments of the present disclosure with reference to FIG. 8A to FIG. 8C. FIG. 8A shows an example interface 800A according to an embodiment of the present disclosure. As shown in FIG. 8A, the interface 800A may include, for example, an icon 810 and a control 820, for example, an appropriate container control. The interface 800A may be provided by the electronic device 100 through a display (for example, the display 194).

As shown in FIG. 8A, for example, a user may drag the icon 810 from a first location shown by a dashed-line icon to a second location shown by a solid-line icon 810 in FIG. 8A. For example, the electronic device 100 may determine that the second location is within a “magnetic force” range 830 of the control 820. It should be understood that the electronic device 100 may detect, in an appropriate manner, a drag action performed by the user on the icon 810.

In some embodiments, the user may release the icon 810 at the second location, to end the drag action on the icon 810. Correspondingly, the icon 810 may further produce a “magnetic force” animation effect associated with the control 820.

In some embodiments, the control 820, for example, may be configured to produce a “magnetic force” attraction animation effect. As shown in FIG. 8B, after the user releases the icon 810, the icon 810 may continue to move toward the control 820 based on a “magnetic force” attraction force produced by the control 820, and move to a third location shown by the solid-line icon 810 in FIG. 8B.

In some embodiments, a motion distance from the second location to the third location may be determined based on the “magnetic force” determined in Formula (1). For example, the motion distance from the second location to the third location may be determined based on one or more of the following: a size of the icon 810 and/or a size of the control 820, a distance from a drag end location of the icon 810 to the control 820, and speed information of the drag action of the icon 810. The motion information may include, for example, an average speed in a predetermined time period before the drag is terminated, an instantaneous speed of the icon when the icon is released, or the like. For example, the motion distance may be directly proportional to the size and/or speed information (for example, an average drag speed before the drag is released) of the control 820, and inversely proportional to the size and/or a distance of the icon 810.

Optionally, a start speed or a start acceleration of the motion from the second location to the third location may be determined based on the “magnetic force” determined in Formula (1). For example, a start speed or a start acceleration of the icon 810 at the second location may be determined based on one or more of the following: the size of the icon 810 and/or the size of the control 820, the distance from the drag end location of the icon 810 to the control 820, and the speed information of the drag action of the icon 810. For example, the start speed or the start acceleration may be directly proportional to the size and/or the speed information (for example, the average drag speed before the drag is released) of the control 820, and inversely proportional to the size and/or the distance of the icon 810.

In some embodiments, the control 820, for example, may be configured to produce a “magnetic force” repulsion animation effect. As shown in FIG. 8C, after the user releases the icon 810, the icon 810 may move away from the control 820 based on a “magnetic force” repulsion force produced by the control 820, and move to a fourth location shown by the solid-line icon 810 in FIG. 8C.

In some embodiments, a motion distance from the second location to the fourth location may be determined based on the “magnetic force” determined in Formula (1). For example, the motion distance from the second location to the fourth location may be determined based on one or more of the following: a size of the icon 810 and/or a size of the control 820, a distance from a drag end location of the icon 810 to the control 820, and speed information of a drag action of the icon 810. For example, the motion distance may be directly proportional to the size of the control 820, and inversely proportional to the size, or speed information (for example, an average drag speed before the drag is released), and/or a distance of the icon 810.

Optionally, a speed or a start acceleration of the motion from the second location to the fourth location may be determined based on the “magnetic force” determined in Formula (1). For example, a start speed or an acceleration of the icon 810 at the second location may be determined based on one or more of the following: the size of the icon 810 and/or the size of the control 820, the distance from the drag end location of the icon 810 to the control 820, and the speed information of the drag action of the icon 810. For example, the start speed or the acceleration may be directly proportional to the size of the control 820, and inversely proportional to the size, or the speed information (for example, the average drag speed before the drag is released), and/or the distance of the icon 810.

Based on such a manner, embodiments of the present disclosure can present an interaction effect like magnetic force “attraction” and/or “repulsion”, so that the electronic device with the screen presents a dynamic effect that conforms to a natural law.

### Example 5

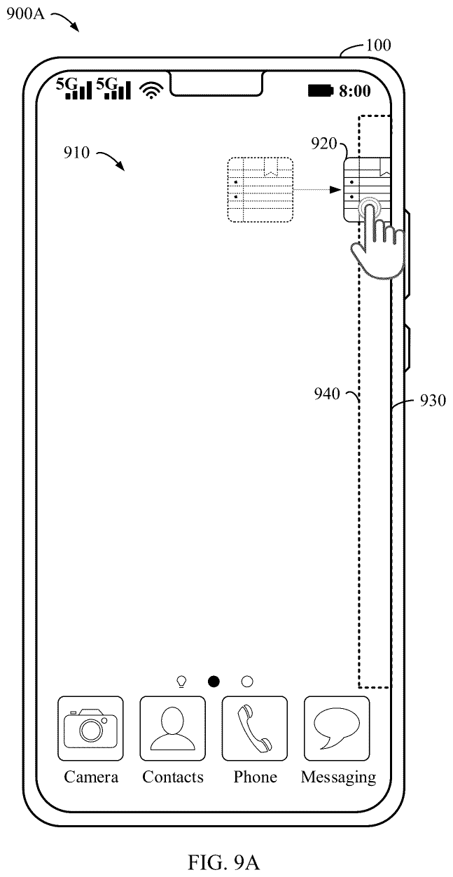

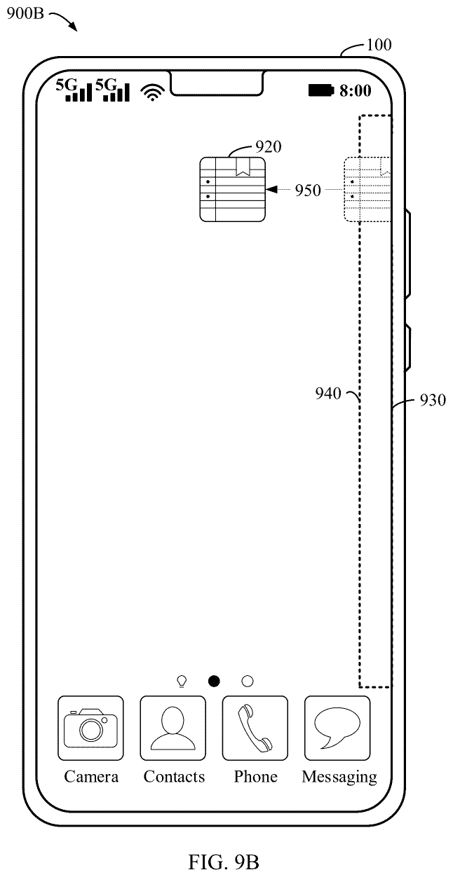

The following describes a display process of a user interface according to some other embodiments of the present disclosure with reference to FIG. 9A and FIG. 9B. As shown in FIG. 9A, the electronic device 100 may provide a user interface 910 through a display (for example, the display 194). In some embodiments, as shown in FIG. 9A, the electronic device 100 may include, for example, a smartphone. The user interface 910 may be, for example, a desktop interface of the smartphone. It should be understood that a specific form of the electronic device in FIG. 9A is only an example, and the electronic device may alternatively include another appropriate type of a device with a screen, and the user interface 910 may alternatively include another appropriate user interface.

In some embodiments, as shown in FIG. 9A, the user interface 910 may include an icon 920. For example, a user may drag the icon 920 from a fifth location shown by a dashed-line icon to a sixth location shown by a solid-line icon in FIG. 9A. In some embodiments, as shown in FIG. 9A, because the sixth location is close to a boundary 930 of the interface 910, only a part of the icon 920 may be presented due to a drag action.

In some embodiments, a “magnetic force” range 940 may be defined for the boundary 930 of the interface 910. When it is detected that the user releases the icon 920 within the “magnetic force” range 940, the “magnetic force” range 940 may enable the icon 920 to produce a corresponding “magnetic force” animation effect.

Specifically, as shown in FIG. 9B, when it is detected that the user releases the icon 920, for example, in the sixth location, the icon 920 may produce the “magnetic force” animation effect. For example, the “magnetic force” animation effect may include a motion 950 from the sixth location to a seventh location shown by the solid-line icon 920 in FIG. 9B. Therefore, embodiments of the present disclosure can present a common collision effect like a natural magnetic force.

In some embodiments, the motion 950 may be determined based on the “magnetic force” defined in Formula (1). For example, a motion distance of the motion 950 may be determined, for example, based on one or more of the following: a size of the icon 920, a distance from a drag end location of the icon 920 to the boundary 930, and speed information of a drag action of the icon 920. The motion information may include, for example, an average speed in a predetermined time period before the drag is terminated, an instantaneous speed of the icon when the icon is released, or the like.

Based on such a manner, embodiments of the present disclosure can present a collision effect like a collision effect of “repulsion” of a natural magnetic force, so that the electronic device with the screen presents a dynamic effect that conforms to a natural law.

### Other Examples

Different types of “magnetic force” animation effect processes are described above with reference to Example 1 to Example 5. It should be understood that, although Example 1 to Example 5 describe the “magnetic force” animation effects in combination with a size change, a color change, a shape change, and an icon motion respectively, other visual features of the UI elements may be changed based on a similar mechanism, and examples thereof may include but be not limited to transparency, brightness, and the like.

In addition, the similar mechanism may be applied to other types of UI element interactions. For example, a user may drag an icon to a “magnetic force” range of a folder, and trigger the folder or the dragged icon to produce a “magnetic force” animation effect.

In some user interfaces, two UI elements may always repel each other and cannot be superimposed. Such a UI element may also be applicable to the “magnetic force” animation effect according to the present disclosure. In an example, when a first UI element moves and enters a “magnetic force” range of a second UI element, the second UI element may be triggered to be moved at a specific distance according to a principle of a “magnetic force” repulsion manner. In some embodiments, a distance at which the second UI element moves may be similarly determined, for example, based on Formula (1).

In another example, when the first UI element moves and enters the “magnetic force” range of the second UI element, a size of the second UI element may be triggered to be reduced according to the principle of the “magnetic force” repulsion manner. In some embodiments, a degree to which the size of the second UI element is reduced may be similarly determined, for example, based on Formula (1).

In another example, when the first UI element moves and enters the “magnetic force” range of the second UI element, the second UI element may be triggered to move away from the first UI element at a specific acceleration in the “magnetic force” repulsion manner. In some embodiments, the acceleration of the motion of the second UI element may be determined, for example, based on the magnetic force determined in Formula (1) and the size of the second UI element.

In still another example, when the first UI element moves and enters the “magnetic force” range of the second UI element, a size of the first UI element may be triggered to be reduced in the “magnetic force” repulsion manner. In some embodiments, a degree to which the size of the first UI element is reduced may be similarly determined, for example, based on Formula (1).

In some embodiments, the “magnetic force” repulsion manner may further, for example, enable the second UI element to remain unchanged, so that the size of the first UI element is reduced based on the “magnetic force” animation effect.

Based on the foregoing “magnetic force” animation effect, embodiments of the present disclosure can enrich UI element interaction scenarios, and provide more realistic interaction experience.

### UI Interaction Example

In some embodiments, a “magnetic force” animation effect in the present disclosure may be applied to different types of controls, for example, an operation type control, a container type space key, a bar type control, a display type control, and a navigation type control. Depending on people's interaction habits, different types of controls may present different “magnetic force” animation effects. For example, Table 1 lists “magnetic force” animation effect solutions that may be applied to different types of controls. A represents a scaling effect (for example, enlarge or reduce) for an object, and B represents a fade-in effect for a background board.

TABLE 1
“Magnetic force” animation effect solutions of different controls

| | | “Magnetic force” |
|---|---|---|
| Control type | Control name | animation effect |
| Operation type | Text selection (menu) | B |
| | Open mode (icon) | B |
| | Toolbar | B |
| | Sharing mode (icon) | B |
| | Search box (ontology) | B |
| | Search box (button) | B |
| | Text box | B |
| | Menu | B |
| | Button (capsule) | A |
| | Button (text) | B |
| | Multi-choice/Check | B |
| | Switch | B |
| | Drop-down button | B |
| | Status button | B |
| | Slide selector | B |
| Container type | List | B |
| | Pop-up box | N/A |
| | <Same as the button> | |
| | Semi-modal (handle bar) | A + B or B |
| Bar type | Index bar | B |
| | Scrollbar | N/A |
| | Rate bar | B |
| | Slide bar | B |
| | Operation block | B |
| Display type | Subtitle (button on the right) | B |
| | Subtitle (text button on the | B |
| | right) | |
| | <Same as the text button> | |
| | Toast prompt (text button) | B |
| Navigation type | Title bar (title text) | B |
| | Title bar (icon) | B |
| | Subtab | B |
| | Bottom tab | B |
| | Navigation point | A |
| | Step selector | B |

The following further describes a UI interaction process with reference to different scenarios.

### Example Scenario 1

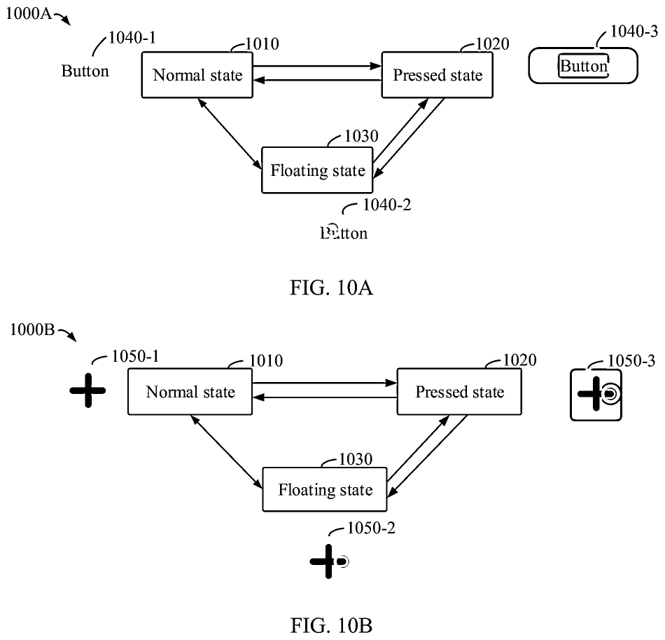

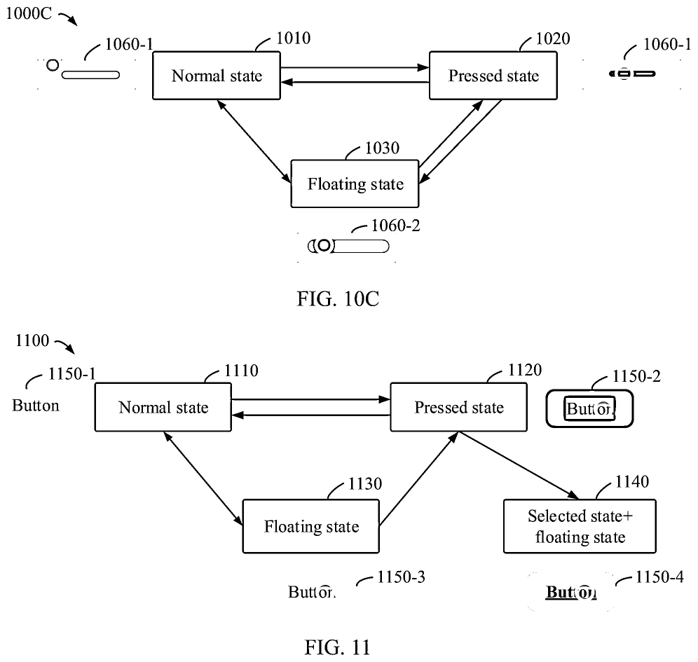

FIG. 10A to FIG. 10C show examples of UI interaction processes according to some embodiments of the present disclosure. As shown in FIG. 10A, in the UI interaction process, a single control may include, for example, three states: a normal state 1010, a pressed state 1020, and a floating state 1030. A button control 1040 is used as an example. In the normal state 1010, for example, the button control 1040 has an initial size and a background color, as shown by a button control 1040-1. For example, a user may switch the button control 1040 to the pressed state 1020 by using a finger to press the button control 1040. In the pressed state 1020, the button control 1040, for example, may have a larger size and a darker background color, as shown by a control 1040-3. After the user releases the finger, the button control 1040 returns to the normal state 1010.

In addition, when a cursor is used for an interaction, and the cursor enters a “magnetic force” range of the button control 1040, the button control 1040 may present the floating state 1030. In the floating state 1030, the button control 1040, for example, may be enlarged to have a larger size, as shown by a control 1040-2. When a cursor location is clicked (for example, clicked by using a mouse), the button control 1040 is switched to the pressed state 1020, and returns to the floating state 1030 after pressing is completed.

FIG. 10B shows switching logic of another type of a control among a normal state 1010, a pressed state 1020, and a floating state 1030. As shown in FIG. 10B, a control 1050 is used as an example. In the normal state 1010, for example, the control 1050 has an initial background board color (for example, white), as shown by a control 1050-1. For example, a user may switch the control 1050 to the pressed state 1020 by using a finger to press the control 1050. In the pressed state 1020, the control 1050, for example, may have a darker background board color (for example, dark gray), as shown by a control 1050-3. After the user releases the finger, the control 1050 returns to the normal state 1010.

In addition, when a cursor is used for an interaction, and the cursor enters a “magnetic force” range of the control 1050, the control 1050 may present the floating state 1030. In the floating state 1030, the control 1050, for example, may have a background board color (for example, light gray) darker than the initial background board color, as shown by a control 1050-2. When a cursor location is clicked (for example, clicked by using a mouse), the control 1050 is switched to the pressed state 1020 (for example, the background board color is switched from light gray to dark gray), and returns to the floating state 1030 after pressing is completed.

FIG. 10C shows switching logic of another type of a control among a normal state 1010, a pressed state 1020, and a floating state 1030. As shown in FIG. 10C, a control 1060 is used as an example. In the normal state 1010, for example, the control 1060 has an initial size and a color, as shown by a control 1060-1. For example, a user may switch the control 1060 to the pressed state 1020 by using a finger to press the control 1060. In the pressed state 1020, the control 1060, for example, may have a smaller size and a darker background board color (for example, dark gray), as shown by a control 1060-3. After the user releases the finger, the control 1060 returns to the normal state 1010.

In addition, when a cursor is used for an interaction, and the cursor enters a “magnetic force” range of the control 1060, the control 1060 may present the floating state 1030. In the floating state 1030, the control 1060, for example, may have a size larger than the initial size, as shown by a control 1060-2. When a cursor location is clicked (for example, clicked by using a mouse), the control 1060 is switched to the pressed state 1020, and returns to the floating state 1030 after pressing is completed.

The switching logic may also be applicable to an interaction of a control such as a capsule button, a navigation point, a button (text), a drop-down button, a slide selector, a subtitle (button on the right), a toast, a title bar (icon button), a step selector, a menu, a text selection menu, a sharing mode, an open mode, a toolbar, a text box, or a handle bar.

### Example Scenario 2

FIG. 11 shows an example of a UI interaction process according to some embodiments of the present disclosure. As shown in FIG. 11, in the UI interaction process, a single control may include, for example, four states: a normal state 1110, a pressed state 1120, a floating state 1130, and a “selected state+floating state” 1140.

A button control 1150 is used as an example. In the normal state 1110, for example, the button control 1150 has an initial size and a background color, as shown by a button control 1150-1. For example, a user may switch the button control 1150 to the pressed state 1120 by using a finger to press the button control 1150. In the pressed state 1120, the button control 1150, for example, may have a larger size and a darker background color, as shown by a button control 1150-2. After the user releases the finger, the button control 1150 returns to the normal state 1110.

In addition, when a cursor is used for an interaction, and the cursor enters a “magnetic force” range of the button control 1150, the button control 1150 may present the floating state 1130. In the floating state 1130, the button control 1150, for example, may have a size larger than the initial size, as shown by a control 1150-3. When a cursor location is clicked (for example, clicked by using a mouse), the button control 1150 is switched to the pressed state 1120, and is switched to the “selected state+floating state” 1140 after pressing is completed. As shown in FIG. 11, in the “selected state+floating state” 1140, the button control 1150 may have a button style different from that in the normal state 1110, to indicate the selected state. For example, the button control 1150 in the “selected state+floating state” 1140 has a background color different from that in the normal state 1110, and a button text style may also be different. In addition, the button control 1150 in the “selected state+floating state” 1140 may further have a larger size than that in the normal state 1110, to indicate the floating state, as shown by a button control 1150-4.

The switching logic is applicable to an interaction of a control such as a status button.

### Example Scenario 3

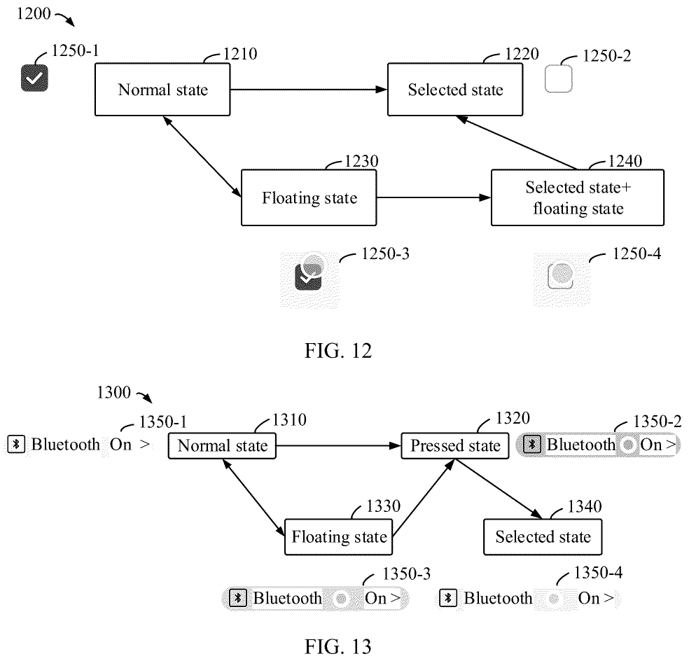

FIG. 12 shows an example of a UI interaction process according to some embodiments of the present disclosure. As shown in FIG. 12, in the UI interaction process, a single control may include, for example, four states: a normal state 1210, a selected state 1220, a floating state 1230, and a “selected state+floating state” 1240.

A selection control 1250 is used as an example. In the normal state 1210, for example, the selection control 1250 has an initial style (for example, with v) and a background board color, as shown by a selection control 1250-1. For example, a user may switch the selection control 1250 to the selected state 1220 by using a finger to press the selection control 1250. In the selected state 1220, the selection control 1250, for example, may have a different style (for example, without v), as shown by a selection control 1250-2.

In addition, when a cursor is used for an interaction, and the cursor enters a “magnetic force” range of the selection control 1250, the selection control 1250 may present the floating state 1230. In the floating state 1230, the selection control 1250, for example, may have a different background board color, as shown by a control 1250-3. When a cursor location is clicked (for example, clicked by using a mouse), the selection control 1250 is switched to the “selected state+floating state” 1240. As shown in FIG. 12, in the “selected state+floating state” 1240, the selection control 1250 may have a style different from that in the normal state 1210, to indicate the selected state, and have a different background board color, to indicate the floating state, as shown by a selection control 1250-4.

The switching logic may be application to an interaction of a control such as a single-choice box, multi-choice/check, a switch, a rate bar, a search box, or a slider/seekbar.

### Example Scenario 4

FIG. 13 shows an example of a UI interaction process according to some embodiments of the present disclosure. As shown in FIG. 13, in the UI interaction process, a single control may include, for example, four states: a normal state 1310, a pressed state 1320, a floating state 1330, and a selected state 1340.

A control 1350 is used as an example. In the normal state 1310, for example, the control 1350 has an initial background color (for example, white), as shown by a control 1350-1. For example, a user may switch the control 1350 to the pressed state 1320 by using a finger to press the control 1350. In the pressed state 1320, the control 1350, for example, may have a darker background color (for example, dark gray), as shown by a control 1350-2. After the user releases the finger, the control 1350 may be switched to the selected state 1340. In the selected state 1340, the control 1350, for example, may have a different background color, to indicate the selected state.

In addition, when a cursor is used for an interaction, and the cursor enters a “magnetic force” range of the control 1350, the control 1350 may present the floating state 1330. In the floating state 1330, the control 1350, for example, may have a different background color (for example, light gray), as shown by a control 1350-3. When a cursor location is clicked (for example, clicked by using a mouse), the control 1350 is switched to the pressed state 1320. Similarly, after the clicking ends, the control 1350 is further switched to the selected state 1340.

The switching logic is applicable to an interaction of a control such as a list and an index bar.

### Example Scenario 5

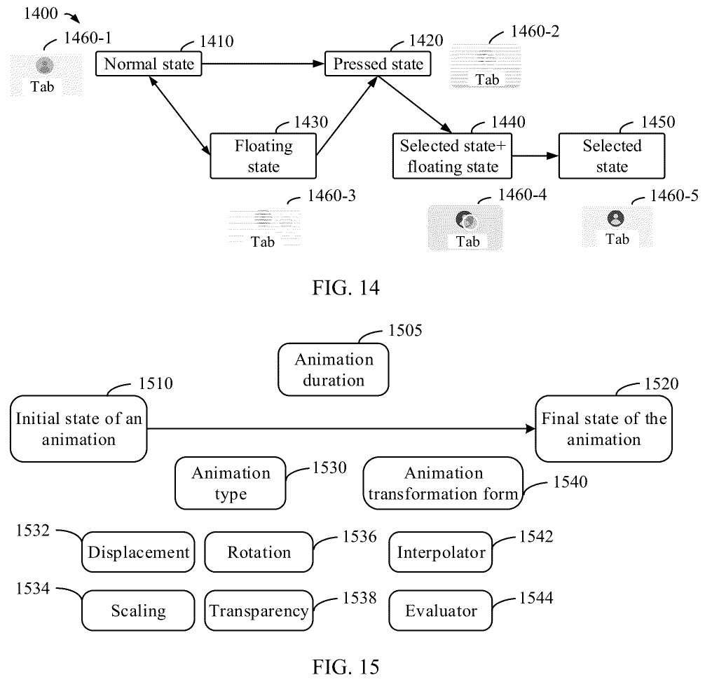

FIG. 14 shows an example of a UI interaction process according to some embodiments of the present disclosure. As shown in FIG. 14, in the UI interaction process, a single control may include, for example, five states: a normal state 1410, a pressed state 1420, a floating state 1430, a “selected state+floating state” 1440, and a selected state 1450.

A tab control 1460 is used as an example. In the normal state 1410, for example, the tab control 1460 has an initial background color (for example, gray of a first depth), and an icon, for example, may be in gray, as shown by a tab control 1460-1. For example, a user may switch the tab control 1460 to the pressed state 1420 by using a finger to press the tab control 1460. In the pressed state 1420, the tab control 1460, for example, may have a darker background color (for example, gray of a second depth), as shown by a tab control 1460-2. After the user releases the finger, the button control 1460 returns to the normal state 1410.

In addition, when a cursor is used for an interaction, and the cursor enters a “magnetic force” range of the tab control 1460, the tab control 1460 may present the floating state 1430. In the floating state 1430, the tab control 1460, for example, may have a different background color (for example, gray of a third depth), as shown by a tab control 1460-3. When a cursor location is clicked (for example, clicked by using a mouse), the tab control 1460 is switched to the pressed state 1420. Similarly, after the clicking ends, the tab control 1460 is further switched to the “selected state+floating state” 1440, where the tab control 1460 has a different background color (for example, gray of the third depth), and an icon color may be configured to a color different from that in the normal state 1410, to indicate the selected state. Further, after the cursor leaves the “magnetic force” range of the tab control 1460, the tab control 1460 is about to be further switched to the selected state 1450, where the tab control 1460 has a background color (for example, gray of the first depth) same as that in the normal state 1400, and the icon color may be configured to a color different from that in the normal state 1410, to indicate the selected state.

The switching logic is applicable to an interaction of a control such as a title bar (tab button), a subtab, or a bottom tab.

### Animation Effect Curve Example

FIG. 15 is a schematic diagram of an animation process and related control logic of a “magnetic force” animation effect according to an embodiment of the present disclosure. In a common operating system of an electronic device, for example, in current mainstream Android system and iOS system, an animation is essentially to display a current interface or control in real time based on a refresh rate, and to use a principle of human persistence of vision to enable a user to feel that a displayed picture is in motion. Therefore, as shown in FIG. 15, the electronic device 100 may first determine an initial state 1510 of a “magnetic force” animation and a final state 1520 of the “magnetic force” animation. In addition, the electronic device 100 may determine an animation duration 1505 that lasts in a process of transforming from the initial state 1510 of the “magnetic force” animation to the final state 1520 of the “magnetic force” animation. In addition, the electronic device 100 may further determine a “magnetic force” animation type 1530 and a “magnetic force” animation transformation form 1540. For example, the “magnetic force” animation type 1530 may include a displacement animation 1532, a scaling animation 1534, a rotation animation 1536, a transparency animation 1538, and the like of a UI element. The “magnetic force” animation transformation form 1540 may be controlled by an interpolator 1542 and an evaluator 1544. For example, a related transformation speed is controlled in the fixed animation duration 1505, and the like.

In some embodiments, the interpolator 1542 may include a curve interpolator that controls the “magnetic force” animation transformation form 1540 from the initial state 1510 to the final state 1520 based on a predetermined curve. For example, the predetermined curve may include a second-order Bézier curve. Specifically, the interpolator 1542 may select two second-order points of the second-order Bezier curve, to control the “magnetic force” animation transformation form 1540. In this way, mutual cooperation between a transformation of the “magnetic force” animation effect and the time produces a rhythmic sense of a motion.

The interpolator 1542 may adjust the curve to accelerate and decelerate a transformation of the “magnetic force” animation instead of transforming at a constant rate. A “motion” transformation is used as an example. The interpolator may adjust the curve so that a motion location dynamically changes with time, instead of moving at a constant speed. Related parameters for nine different rhythms of Bézier curves in a particular building platform are as follows. The curves discussed above (for example, the curves 310, 320, 330, 340, 420, 430, 440, 450, 650, 660, 750, and 760) may be one of the nine Bezier curves below. It should be noted that, although some examples are described in a context of the present disclosure by using the second-order Bézier curve as an animation effect curve, embodiments of the present disclosure are not limited thereto, and any curve form may be equivalently used as the animation effect curve to control an animation transformation of the UI element. For example, such a curve form includes but is not limited to a first-order Bézier curve, a third-order or higher-order Bézier curve, another known or future-discovered curve form, or even a straight line.

TABLE 2
Different types of interpolators

| Interpolator | Description |
|---|---|
| Bezier: (0.0, 0.1) | 01-cubic_bezier_interpolator_type_0_100 |
| | Android interpolator: |
| | cubic_bezier_interpolator_type_0_100.xml |
| | AE: 0-100 |
| Bezier: (0.1, 0, 0.1, 1) | 02-cubic_bezier_interpolator_type_10_90 |
| | Android interpolator: |
| | cubic_bezier_interpolator_type_10_90.xml |
| | AE: 10-90 |
| Bezier: (0.2, 0.0, 1) | 03-cubic_bezier_interpolator_type_20_80 |
| | Android interpolator: |
| | cu_bic_bezier_interpolator_type _20_80.xml |
| | AE: 20-80 |
| Bezier: (0.2, 0, 0.2, 1) | 04-cubrc_bezier_interpolator_type_20_90 |
| | Android interpolator: |
| | cubic_bezier_interpolator_type_20_90.xml |
| | AE: 20-90 |
| Bezier: (0.33, 0, 0.67, | 05-cubic_bezier_interpolator_type_33_33 |
| 1) | Android interpolator: |
| | cubic_bezier_interpolator_type_33_33.xml |
| | AE: 33-33 |
| Bezier: (0.4, 0, 0.4, 1) | 06-cubic_bezier_interpolator_type_40_60 |
| | Android interpolator: |
| | cubic_bezier_interpolator_type_40_60.xml |
| | AE: 40-60 |
| Bezier: (0.4, 0, 0.1, 1) | 07-cubic_bezier_interpolator_type_40_90 |
| | Android interpolator: |
| Interpolator | Description |
| | cubic_bezier_intetpolator_type_40_90.xml |
| | AE: 40-90 |
| Bezier: (0.4, 0, 0.2, 1) | 08-cubic_bezier_intetpolator _type_70_80 |
| | Android interpolator: |
| | cubic_bezier_interpolator_type_70_80.xml |
| | AE: 70-80 |
| Bezier: (0.9, 0, 0.9, 1) | 09-cubic_bezier_intetpolator_type_90_10 |
| | Android interpolator: |
| | cubic_bezier_intetpolator_type_90_10.xml |
| | AE: 90-10 |

In the foregoing nine different rhythms, a Bezier curve that slides along a hand of a user may appropriately try 40-60; 33-33 may be a Bézier curve that follows a hand speed; and 70-80 is a curve with a relatively strong rhythm, and may be used to highlight an interesting scenario. Based on the foregoing analysis, a Bézier curve may be selected for an interpolator of a first motion of a second UI element 344, and a specific coordinate may be obtained through analysis of various parameters configured for a “magnetic force” animation effect. In addition, it should be noted that coordinates of two points of the Bézier curve in embodiments of the present disclosure may be randomly determined, and are not limited to the foregoing nine curves. The coordinates of the two points may be (x1,y1) and (x2,y2), where values of x1, y1, x2, and y2 may range from 0 to 1, and usually a decimal place may be used.

In some embodiments, an interpolator 1542 may also use an elastic force curve model to control a “magnetic force” animation transformation form 1540 from an initial state 1510 to a final state 1520. For example, the elastic force curve model may include an elastic force curve of critical damping. Usually, the elastic force curve may use different states, namely, critical damping, underdamping, and overdamping, in different operation scenarios. In different damping states, elastic force curves of displacement time may be different. Specifically, three cases are as follows: A square of damping is equal to four times mass multiplied by rigidity, which is the critical damping. Further, if the damping is too large, it is overdamping. If the rigidity is large, it is underdamping. In particular, if the square of the damping is less than four times the mass multiplied by the rigidity, it is underdamping. If the square of the damping is greater than four times the mass multiplied by the rigidity, it is overdamping.

In a specific implementation of the elastic force model, a damping vibration formula of an elastic engine based on the Hooke's law is as follows:

$$f = ma \qquad ( 2 )$$

$$- kx - g \frac{dx}{dt} = m \frac{{d}^{2} x}{{dt}^{2}} \qquad ( 3 )$$

f represents a force in a vibration process, m represents mass, a represents an acceleration, k represents an elastic system (rigidity), x represents a spring deformation amount, g represents a resistance coefficient (damping), and t represents time. In a specific setting, a user of the electronic device 100 only needs to determine the spring deformation amount x (namely, a distance of a second motion) that needs to be generated, and other parameters may be adjustable parameters. In some embodiments, related recommended values of these adjustable parameters may be provided through human factors research, to be used by an application. Certainly, the application may also customize these adjustable parameters as required.

### System Implementation Example

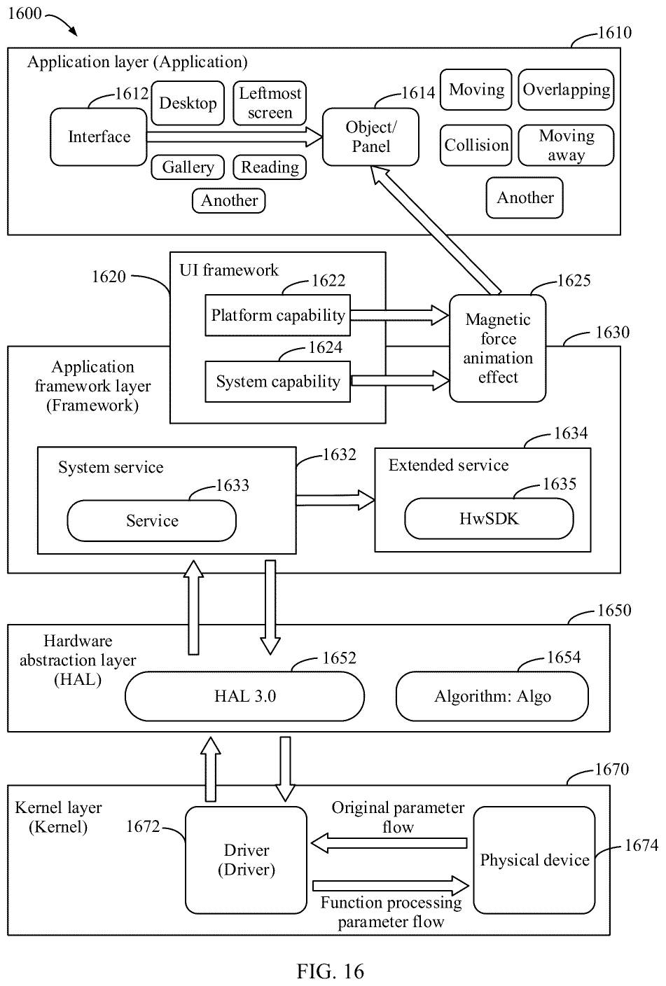

FIG. 16 is a schematic diagram of a system framework 1600 for implementing a capability or function of a “magnetic force” animation effect according to an embodiment of the present disclosure. In some embodiments, an animation effect capability of a UI framework is implemented based on an overall architecture of an operating system (for example, Android or HarmonyOS) of an electronic device, and may include mainstream four-layer logic processing. A data processing procedure is presented to a user from a bottom layer to a top layer. The user may mainly use and experience an animation effect function at an application layer. In embodiments of the present disclosure, FIG. 16 describes a capability interaction relationship between a desktop and the UI framework. Specifically, as shown in FIG. 16, the system framework 1600 may include an application layer 1610, an application framework layer 1630, a hardware abstraction layer 1650, and a kernel layer 1670. The application layer 1610 may include an interface 1612, for example, a desktop, a leftmost screen, a gallery, reading, or another appropriate user interface. Operations on an object/panel 1614 may be implemented in the interface 1612. The operations may include, for example, a moving operation, an overlapping operation, a collision operation, a moving away operation, and another operation. The application framework layer 1630 may include a system service 1632 and an extended service 1634. The system service 1632 may include various system services, for example, a service 1633. The extended service 1634 may include various extended services, for example, a HwSDK 1635. The hardware abstraction layer (HAL) 1650 may include a HAL 3.0 1652 and an algorithm Algo 1654. The kernel layer 1670 may include a driver 1672 and a physical device 1674. The physical device 1674 may provide an original parameter flow to the driver 1672, and the driver 1672 may provide a function processing parameter flow to the physical device 1674. As further shown in FIG. 16, a UI framework 1620 for implementing a magnetic force animation effect 1625 may be implemented between the application layer 1610 and the application framework layer 1630. The UI framework 1620 may include a platform capability 1622 and a system capability 1624, both of which may be used to provide the magnetic force animation effect 1625. The magnetic force animation effect 1625 may be provided to the object/panel 1614 of the application layer 1610, so that the object/panel 1614 presents a corresponding animation effect.

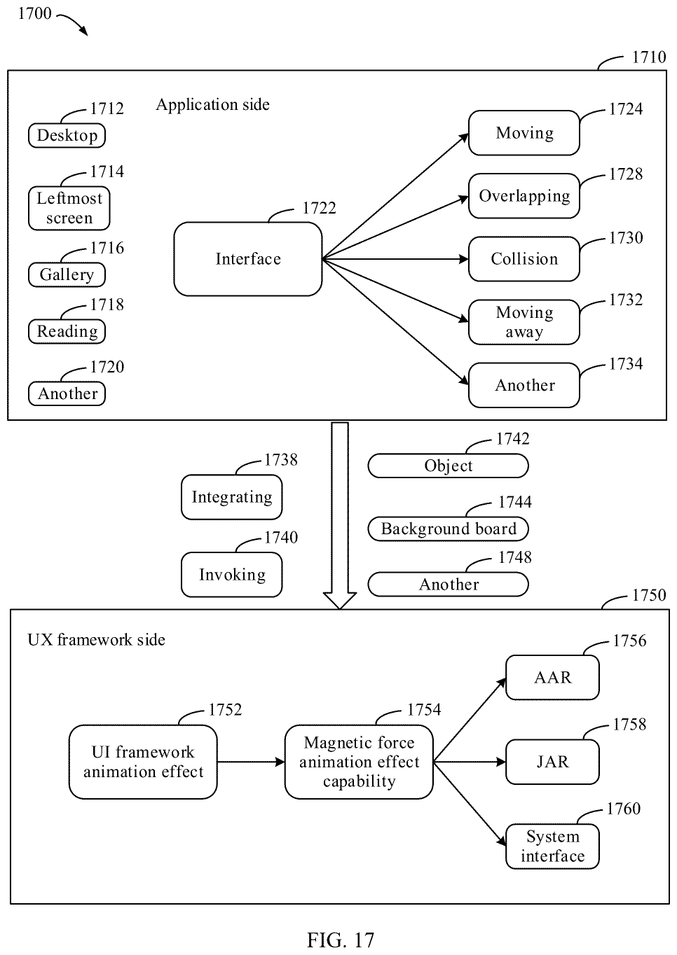

FIG. 17 is a schematic diagram 1700 of a relationship between an application side and a UX (user experience) framework side that are related to a capability or function of a “magnetic force” animation effect according to an embodiment of the present disclosure. As shown in FIG. 17, the application side 1710 may include an interface 1722. For example, the interface 1722 may include but be not limited to a desktop 1712, a leftmost screen 1714, a gallery 1716, reading 1718, and another interface 1720. A UI element in the interface 1722 may implement operations, for example, a moving operation 1724, an overlapping operation 1728, a collision operation 1730, a moving away operation 1732, and another operation 1734. The UX framework side 1750 may include a UI framework animation effect 1752. The UI framework animation effect 1752 may implement a magnetic force animation effect capability 1754. The magnetic force animation effect capability 1754 may be implemented in a manner such as an AAR format 1756, a JAR format 1758, and a system interface 1760. The application side 1710 may invoke, in a manner such as integrating 1738 and invoking 1740, the capability or function that is of the “magnetic force” animation effect and that is provided by the UX framework side 1750, to implement an animation effect for an object 1742, a background board 1744, or another 1748. Through an interaction between the application side 1710 and the UX framework side 1750, embodiments of the present disclosure implement a new magnetic force “animation effect”, so that original independent UI elements (for example, a cursor and a control) are associated.

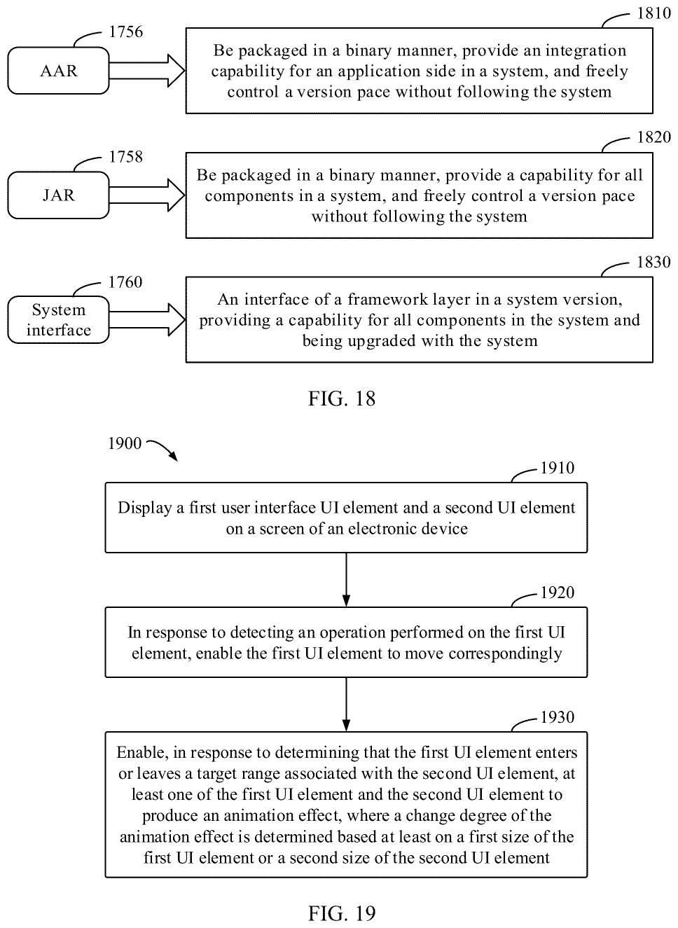

FIG. 18 is a schematic diagram of a specific description of three manners of implementing a capability or function of a “magnetic force” animation effect according to an embodiment of the present disclosure. As shown in FIG. 18, a relationship 1810 between the AAR format 1756 and a system of an electronic device 100 is as follows: The AAR format 1756 is packaged in a binary manner, provides an integration capability for an application side in the system, and may freely control a version pace without following the system. A relationship 1820 between the JAR format 1758 and the system of the electronic device 100 is as follows: The JAR format 1758 is packaged in a binary manner, provides a capability for all components in the system, and may freely control the version pace without following the system. A relationship 1830 between the system interface 1760 and the system of the electronic device 100 is as follows: The system interface 1760 is an interface of a framework layer in a system version, provides a capability for all components in the system, and is upgraded with the system. More specifically, the integrating manner may be an AAR manner and a JAR package manner, and the invoking manner may be a system interface manner. Therefore, a scenario to which embodiments of the present disclosure are applicable is not limited to any particular scenario, but a manner of displaying a “magnetic force” animation effect capability may be different. In other words, functions of the methods described above in the present disclosure may be implemented by using an AAR file, a JAR file, and/or a system interface of the electronic device 100. In this manner, the capability or function of the “magnetic force” animation effect may be simply and conveniently implemented and provided to an application of the electronic device, for example, a desktop.

In embodiments of the present disclosure, interface design and solution implementation include design and implementation of implementing magnetic force model capabilities. The following is an example of the design and implementation of magnetic force model capabilities.

```
  // Listen to a touch down event.
  // Initialize a magnetic force field. The parameter is a center point coordinate of a touch
view, namely, a magnetic force center point.
  MagneticForceField field = new MagneticForceField(pos[0], pos[1]);
  // Configure a magnetic force type: scaling, fade-in, or fade-out.
  field.setMagneticForceType(type);
  // Configure a magnetic force duration.
  field.setDuration(duration);
  // Configure a magnetic force impact range.
  field.setImpactRadius(maxRadius);
  field.setImpactMinimumRadius(minRadius);
  // Configure an amplitude coefficient.
  field.setAmplitudeCoefficient(amplitudeCoefficient);
  // Configure a magnetic force propagation speed.
  field.setMagneticForceVelocity(MagneticForceVelocity);
  // Configure a magnetic force coefficient.
  field.setMagneticForceCoefficient(MagneticForceCoefficient)
  // Define an element of the magnetic force field. The parameter is a center point
coordinate (belonging to a same coordinate system as a magnetic force source) of each element.
  MagneticForceAsteroid asteroid = new MagneticForceAsteroid(pos[0], pos[1]) {
    @Override
    public void onUpdate(float x, float y) {
      // Update in a magnetic force animation process
    }
    @Override
    public void onEnd(float valueX, float valueY) {
      // Execution after the magnetic force animation ends
    }
  };
  // Configure a magnetic force motion interpolator.
  asteroid.setInterpolator(PathInterpolatorCompat.create(x1,y1,x2,y2));
  // Add the element to the magnetic force.
  field.addAsteroid(asteroid);
```

The following table describes the related parameters.

| Parameter name | Parameter meaning | Value constraint |
|---|---|---|
| Magnetic force type | Magnetic force type | MagneticForceField. |
| MagneticForceType | | MagneticForceType.SCALE: |
| | | scaling |
| | | MagneticForceField. |
| | | MagneticForceType.ALPHA: |
| | | fading. The default value is SCALE. |
| Magnetic force duration | Magnetic force | (0-+∞). The default value is 500 ms. |
| Duration | animation duration | |
| Upper limit of the magnetic | Elements greater than | (0-+∞). The default value is 500. |
| force range R: | this range from the | |
| ImpactRadius | magnetic force point are | |
| | not affected by the | |
| | magnetic force. | |
| Lower limit of the | Elements not greater | [0-+∞). The default value is 0. |
| magnetic force range | than this range from the | |
| ImpactMinimumRadius | magnetic force point are | |
| | not affected by the | |
| | magnetic force. | |
| Amplitude coefficient | Used to calculate an | [0-+∞). The default value is 20. |
| amplitudeCoefficient | amplitude of the | Assuming that a distance between an |
| | magnetic force | element and the center point is r, a |
| | animation effect | displacement amplitude is a*R/r. R |
| | | is the upper limit of the magnetic |
| Parameter name | Parameter meaning | Value constraint |
| | | force range. |
| | | It may also be dynamically |
| | | determined based on the process |
| | | discussed above, and a proportional |
| | | relationship needs to be similar. |
| Magnetic force propagation | Used to calculate a delay | An element (namely, an element |
| speed (s): | of a magnetic force | closest to the center point in the |
| MagneticForceVelocity | animation | impact range, and a distance r0 |
| | | between the element and the center |
| | | point) of a first wave motion has no |
| | | delay, and a delay of another |
| | | affected element (a distance r |
| | | between the element and the center |
| | | point) is (r − r0)/s. |
| Magnetic force coefficient | Optional | When an interpolator is configured |
| G: | | for an element, an animation law is |
| MagneticForceCoefficient | | determined by the interpolator. If no |
| | | motion interpolator is configured, a |
| | | physical model is used to calculate a |
| | | motion curve. Motion acceleration |
| | | a = GM/(r*r), where Mis mass of the |
| | | magnetic source and the default |
| | | value is 1. r is a displacement from |
| | | an element to the magnetic force |
| | | source, r is refreshed for each frame, |
| | | and the element performs an |
| | | acceleration motion. |

### Example Method

FIG. 19 is a flowchart of an example process 1900 of a user interface method according to an embodiment of the present disclosure. The process 1900 may be implemented, for example, by the electronic device 100.

As shown in FIG. 19, in a block 1910, the electronic device 100 displays a first user interface UI element and a second UI element on a screen.

In a block 1920, in response to detecting an operation performed on the first UI element, the electronic device 100 enables the first UI element to move correspondingly.

In a block 1930, the electronic device 100 enables, in response to determining that the first UI element enters or leaves a target range associated with the second UI element, at least one of the first UI element and the second UI element to produce an animation effect, where a change degree of the animation effect is determined based at least on a first size of the first UI element or a second size of the second UI element.

In some embodiments, the change degree of the animation effect is further determined based on speed information associated with the motion of the first UI element, and the speed information indicates at least one of the following: a speed at which the first UI element enters or leaves the target range; or an average speed of the first UI element in a target time period, where the target time period is determined based on a moment at which the first UI element enters or leaves the target range.

In some embodiments, the change degree of the animation effect is directly proportional to the first size or the second size and inversely proportional to the speed indicated by the speed information.

In some embodiments, the enabling at least one of the first UI element and the second UI element to produce an animation effect includes: enabling the at least one of the first UI element and the second UI element to move a target distance, where the change degree indicates a length of the target distance; or changing a visual feature of the at least one of the first UI element and the second UI element, where the visual feature includes at least one of the following: a size, a color, a shape, transparency, or brightness, and the change degree indicates a change magnitude of the visual feature.

In some embodiments, the animation effect is determined based on a predefined curve that changes over time. The predefined curve is a Bézier curve or an elastic force curve.

In some embodiments, the animation effect includes a first animation effect produced by the second UI element at a first moment, the screen of the electronic device further displays a third UI element, and the method further includes: enabling the third UI element to produce a second animation effect at a second moment, where the second moment is later than the first moment.

In some embodiments, the second moment is determined based on a distance from the third UI element to the first UI element at the first moment.

In some embodiments, the enabling, in response to determining that the first UI element enters or leaves the target range associated with the second UI element, at least one of the first UI element and the second UI element to produce an animation effect includes: in response to detecting that the motion enables the first UI element to enter the target range at a third moment, enabling the at least one of the first UI element and the second UI element to produce the first animation effect; and in response to detecting that the motion enables the second UI element to leave the target range at a fourth moment and that a difference between the fourth moment and the third moment is less than an animation effect duration of the first animation effect: enabling the at least one of the first UI element and the second UI element to stop presenting the first animation effect; and enabling the at least one of the first UI element and the second UI element to start presenting the second animation effect.

In some embodiments, the target range is determined based on the second size of the second UI element.

In some embodiments, the first UI element is a cursor element, the second UI element is a control element, and the enabling at least one of the first UI element and the second UI element to produce an animation effect includes: in response to determining that the first UI element enters the target range, enabling the second UI element to be switched from a first state to a floating state, where a size or a background board style of the second UI element in the floating state is different from that of the second UI element in the first state; or in response to determining that the first UI element leaves the target range, enabling the second UI element to exit the floating state.

In some embodiments, the method further includes: determining, based on a comparison between the target range and location information that is associated with the first UI element, that the first UI element enters or leaves the target range associated with the second UI element, where the location information indicates a central location or a boundary location of the first UI element.

In some embodiments, a function of the method is implemented by using at least one of an AAR file, a JAR file, and a system interface of the electronic device.

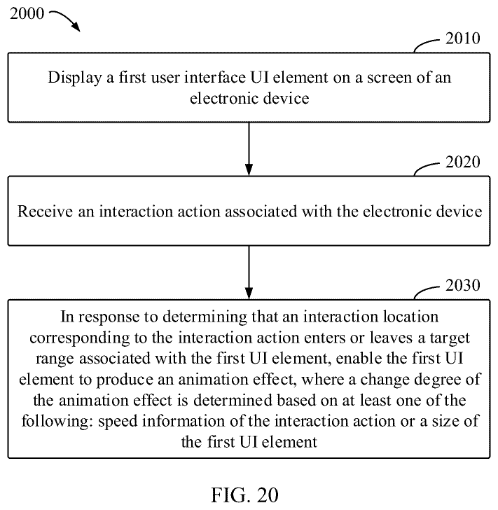

FIG. 20 is a flowchart of an example process 2000 of a user interface display method according to an embodiment of the present disclosure. The process 2000 may be implemented, for example, by the electronic device 100.

As shown in FIG. 20, in a block 2010, the electronic device 100 displays a first user interface UI element on a screen.

In a block 2020, the electronic device 100 receives an interaction action associated with the electronic device 100.

In a block 2030, in response to determining that an interaction location corresponding to the interaction action enters or leaves a target range associated with the first UI element, the electronic device 100 enables the first UI element to produce an animation effect, where a change degree of the animation effect is determined based on at least one of the following: speed information of the interaction action or a size of the first UI element.

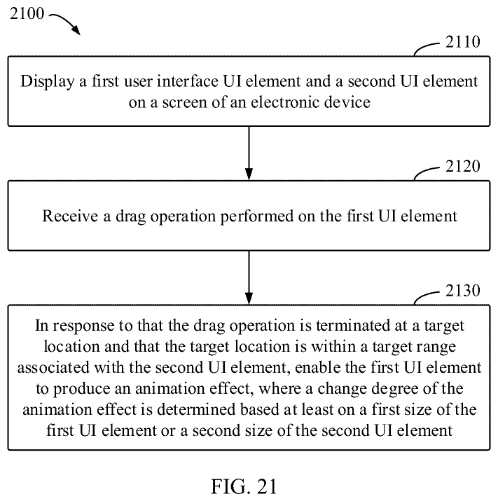

FIG. 21 is a flowchart of an example process 2100 of a user interface method according to an embodiment of the present disclosure. The process 2100 may be implemented, for example, by the electronic device 100.

As shown in FIG. 21, in a block 2110, the electronic device 100 displays a first user interface UI element and a second UI element on a screen.

In a block 2120, the electronic device 100 receives a drag operation performed on the first UI element.

In a block 2130, in response to that the drag operation is terminated at a target location and that the target location is within a target range associated with the second UI element, the electronic device 100 enables the first UI element to produce an animation effect, where a change degree of the animation effect is determined based at least on a first size of the first UI element or a second size of the second UI element. The interface display method in embodiments of the present disclosure may be applied to a plurality of electronic devices. For example, the electronic device may be, for example, a mobile phone, a tablet computer (Tablet Personal Computer), a digital camera, a personal digital assistant (personal digital assistant, PDA for short), a navigation apparatus, a mobile internet device (Mobile Internet Device, MID), a wearable device (Wearable Device), and another device that can perform object editing. In addition, an object editing solution in embodiments of the present disclosure may not only be used as a function of an input method, but also be implemented as a function of an operating system of an electronic device.

All or some of the foregoing embodiments may be implemented by software, hardware, firmware, or any combination thereof. When a software program is used for implementation, all or some of embodiments may be implemented in a form of a computer program product. The computer program product includes one or more computer instructions. When the computer program instructions are loaded and executed on a computer, the procedures or functions according to embodiments of the present disclosure are all or partially generated. The computer may be a general-purpose computer, a dedicated computer, a computer network, or another programmable apparatus. The computer instructions may be stored in a computer-readable storage medium or may be transmitted from one computer-readable storage medium to another computer-readable storage medium. For example, the computer instructions may be transmitted from one website, computer, server, or data center to another website, computer, server, or data center in a wired (for example, a coaxial cable, an optical fiber, or a digital subscriber line (DSL)) or wireless (for example, infrared, radio, or microwave) manner. The computer-readable storage medium may be any usable medium accessible by the computer, or a data storage device, such as a server or a data center, integrating one or more usable media. The usable medium may be a magnetic medium (for example, a floppy disk, a hard disk drive, or a magnetic tape), an optical medium (for example, a DVD), a semiconductor medium (for example, a solid-state drive Solid-State Drive (SSD)), or the like.

In general, various example embodiments of the present disclosure may be implemented in hardware or a dedicated circuit, software, logic, or any combination thereof. Some aspects may be implemented in hardware while other aspects may be implemented in firmware or software that may be executed by a controller, a microprocessor, or another electronic device. For example, in some embodiments, various examples (for example, a method, an apparatus, or a device) of the present disclosure may be partially or all implemented on the computer-readable medium. When various aspects of embodiments of the present disclosure are illustrated or described as block diagrams, flowcharts, or represented by some other graphics, it should be understood that the blocks, apparatuses, systems, techniques, or methods described herein may be implemented as non-limiting examples in hardware, software, firmware, a dedicated circuit or logic, general-purpose hardware or a controller, or another electronic device, or a combination thereof.

The present disclosure further provides at least one computer program product stored on a non-transitory computer-readable storage medium. The computer program product includes computer-executable instructions. The computer-executable instructions, for example, are included in a program module executed in a component on a target physical or virtual processor, and are used to perform the example methods or example processes 400, 1400, and 1500 described above with reference to FIG. 4A and FIG. 4B, FIG. 14, and FIG. 15. In general, the program module may include a routine, a program, a library, an object, a class, a component, a data structure, and the like, and execute a specific task or implement a specific abstract data structure. In various embodiments, functions of program modules may be combined or split between the described program modules. The computer-executable instructions for the program module may be executed locally or in a distributed device. In the distributed device, the program module may be located in both a local storage medium and a remote storage medium.

Program code used to implement the methods of the present disclosure may be written in one or more programming languages. The computer program code may be provided to a processor of a general-purpose computer, a dedicated computer, or another programmable data processing apparatus, so that when the program code is executed by the computer or the another programmable data processing apparatus, functions/operations specified in the flowcharts and/or the block diagrams are implemented. The program code may be executed all on a computer, partially on a computer, as an independent software package, partially on a computer and partially on a remote computer, or all on a remote computer or server. In the context of the present disclosure, the computer program code or related data may be carried by any appropriate carrier, so that a device, an apparatus, or a processor can perform the various processes and operations described above. For example, the carrier includes a signal, a computer-readable medium, and the like.

All or some of the foregoing embodiments may be implemented by software, hardware, firmware, or any combination thereof. When software is used for implementation, all or some of embodiments may be implemented in a form of a computer program product. The computer program product includes one or more computer instructions. When the computer program instructions are loaded and executed on a computer, the procedures or functions according to embodiments of this disclosure are all or partially generated. The computer may be a general-purpose computer, a dedicated computer, a computer network, or another programmable apparatus. The computer instructions may be stored in a computer-readable storage medium or may be transmitted from one computer-readable storage medium to another computer-readable storage medium. For example, the computer instructions may be transmitted from one website, computer, server, or data center to another website, computer, server, or data center in a wired (for example, a coaxial cable, an optical fiber, or a digital subscriber line) or wireless (for example, infrared, radio, or microwave) manner. The computer-readable storage medium may be any usable medium accessible by the computer, or a data storage device, such as a server or a data center, integrating one or more usable media. The usable medium may be a magnetic medium (for example, a floppy disk, a hard disk drive, or a magnetic tape), an optical medium (for example, a DVD), a semiconductor medium (for example, a solid-state drive), or the like.

A person of ordinary skill in the art may understand that all or some of the procedures in the method embodiments may be implemented by a computer program instructing related hardware. The program may be stored in a computer-readable storage medium. When the program is executed, the procedures in the method embodiments may be performed. The foregoing storage medium includes: any medium that can store program code, such as a ROM, a random access memory RAM, a magnetic disk, or an optical disc. The computer-readable medium may be a computer-readable signal medium or a computer-readable storage medium. The computer-readable medium may include but be not limited to an electronic, magnetic, optical, electromagnetic, infrared, or semiconductor system, apparatus, or device, or any suitable combination thereof. More detailed examples of the machine-readable storage medium include an electrical connection with one or more wires, a portable computer disk, a hard disk drive, a random access memory (RAM), a read-only memory (ROM), an erasable programmable read-only memory (EPROM or a flash memory), an optical fiber, a portable compact disc read-only memory (CD-ROM), an optical storage device, a magnetic storage device, or any suitable combination thereof.

In addition, while operations are described in a particular order, this should not be understood as requiring such operations to be completed in the particular order shown or in a successive order, or performing all the illustrated operations to obtain desired results. In some cases, multitasking or parallel processing is advantageous. Similarly, while the foregoing descriptions include some specific implementation details, this should not be construed as limitations on the scope of any invention or claims, but rather as descriptions of specific embodiments that may be specific to a specific invention. Some features described in this specification in a context of separate embodiments may alternatively be integrated into a single embodiment. Conversely, various features described in a context of a single embodiment may alternatively be implemented separately in a plurality of embodiments or in any suitable sub-combination.

Although the subject matter has been described in language specific to structural features and/or methodological actions, it should be understood that the subject matter defined in the appended claims is not limited to the specific features or actions described above. Rather, the specific features and actions described above are disclosed as example forms of implementing the claims. The various examples and processes described above may be used independently of each other, or may be combined in various manners. Different combinations and sub-combinations are intended to fall within the scope of the present disclosure, and some steps or processes may be omitted in some implementations. The foregoing descriptions are merely specific implementations of embodiments of the present disclosure, but are not intended to limit the protection scope of embodiments of the present disclosure. Any variation or replacement within the technical scope disclosed in embodiments of the present disclosure shall fall within the protection scope of embodiments of the present disclosure. Therefore, the protection scope of the embodiments of the present disclosure shall be subject to the protection scope of the claims.

1. A user interface display method, comprising:
displaying a first user interface (UI) element and a second UI element on a screen of an electronic device;
in response to detecting an operation performed on the first UI element, enabling the first UI element to move; and
enabling, in response to determining that the first UI element enters or leaves a target area associated with the second UI element, at least one of the first UI element and the second UI element to produce an animation effect causing a change in the display, wherein a degree of the change is determined based at least on a first size of the first UI element or a second size of the second UI element.

2. The method according to claim 1, wherein the degree of change is further determined based on speed information associated with the motion of the first UI element, and the speed information indicates at least one of the following:
a speed at which the first UI element enters or leaves the target area; or
an average speed of the first UI element in a target time period, wherein the target time period is determined based on a moment at which the first UI element enters or leaves the target area.

3. The method according to claim 2, wherein the degree of change is directly proportional to the first size or the second size and inversely proportional to the speed indicated by the speed information.

4. The method according to claim 1, wherein the degree of change indicates a length of the target distance, and wherein the enabling at least one of the first UI element and the second UI element to produce an animation effect comprises:
changing a visual feature of the at least one of the first UI element and the second UI element, wherein the visual feature comprises at least one of the following: a size, a color, a shape, transparency, or brightness, and the degree of change indicates a magnitude of change of the visual feature.

5. The method according to claim 1, wherein the animation effect comprises a first animation effect produced by the second UI element at a first moment, the screen of the electronic device further displays a third UI element, and the method further comprises:
enabling the third UI element to produce a second animation effect at a second moment, wherein the second moment is later than the first moment.

6. The method according to claim 5, wherein the second moment is determined based on a distance from the third UI element to the first UI element at the first moment.

7. The method according to claim 1, wherein the enabling, in response to determining that the first UI element enters or leaves a target area associated with the second UI element, at least one of the first UI element and the second UI element to produce an animation effect comprises:
in response to detecting that the motion enables the first UI element to enter the target area at a third moment, enabling the at least one of the first UI element and the second UI element to produce the first animation effect; and
in response to detecting that the motion enables the second UI element to leave the target area at a fourth moment and that a difference between the fourth moment and the third moment is less than an animation effect duration of the first animation effect:
enabling the at least one of the first UI element and the second UI element to stop presenting the first animation effect; and
enabling the at least one of the first UI element and the second UI element to start presenting the second animation effect.

8. The method according to claim 1, wherein the target area is determined based on the second size of the second UI element.

9. The method according to claim 1, wherein the first UI element is a cursor element, the second UI element is a control element, and the enabling at least one of the first UI element and the second UI element to produce an animation effect comprises:
in response to determining that the first UI element enters the target area, enabling the second UI element to be switched from a first state to a floating state, wherein a size or a background board style of the second UI element in the floating state is different from that of the second UI element in the first state; or
in response to determining that the first UI element leaves the target area, enabling the second UI element to exit the floating state.

10. The method according to claim 1, further comprising:
determining, based on a comparison between the target area and location information that is associated with the first UI element, that the first UI element enters or leaves the target area associated with the second UI element, wherein the location information indicates a central location or a boundary location of the first UI element.

11. An electronic device, comprising a memory that stores instructions and a processor configured to execute the instructions, wherein when the instructions are executed by the processor, the electronic device is enabled to perform the operations:
displaying a first user interface (UI) element and a second UI element on a screen of an electronic device;
in response to detecting an operation performed on the first UI element, enabling the first UI element to move; and
enabling, in response to determining that the first UI element enters or leaves a target area associated with the second UI element, at least one of the first UI element and the second UI element to produce an animation effect causing a change in the display, wherein a degree of the change is determined based at least on a first size of the first UI element or a second size of the second UI element.

12. The electronic device according to claim 11, wherein
the degree of change is further determined based on speed information associated with the motion of the first UI element, and the speed information indicates at least one of the following:
a speed at which the first UI element enters or leaves the target area; or
an average speed of the first UI element in a target time period, wherein the target time period is determined based on a moment at which the first UI element enters or leaves the target area.

13. The electronic device according to claim 12, wherein the degree of change is directly proportional to the first size or the second size and inversely proportional to the speed indicated by the speed information.

14. The electronic device according to claim 11, wherein the degree of change indicates a length of the target distance, and wherein the enabling at least one of the first UI element and the second UI element to produce an animation effect comprises:
changing a visual feature of the at least one of the first UI element and the second UI element, wherein the visual feature comprises at least one of the following: a size, a color, a shape, transparency, or brightness, and the degree of change indicates a magnitude of change of the visual feature.

15. The electronic device according to claim 11, wherein the animation effect comprises a first animation effect produced by the second UI element at a first moment, the screen of the electronic device further displays a third UI element, and the operations further comprising:
enabling the third UI element to produce a second animation effect at a second moment, wherein the second moment is later than the first moment.

16. The electronic device according to claim 15, wherein the second moment is determined based on a distance from the third UI element to the first UI element at the first moment.

17. The electronic device according to claim 11, wherein the enabling, in response to determining that the first UI element enters or leaves a target area associated with the second UI element, at least one of the first UI element and the second UI element to produce an animation effect comprises:
in response to detecting that the motion enables the first UI element to enter the target area at a third moment, enabling the at least one of the first UI element and the second UI element to produce the first animation effect; and
in response to detecting that the motion enables the second UI element to leave the target area at a fourth moment and that a difference between the fourth moment and the third moment is less than an animation effect duration of the first animation effect:
enabling the at least one of the first UI element and the second UI element to stop presenting the first animation effect; and
enabling the at least one of the first UI element and the second UI element to start presenting the second animation effect.

18. The electronic device according to claim 11, wherein the first UI element is a cursor element, the second UI element is a control element, and the enabling at least one of the first UI element and the second UI element to produce an animation effect comprises:
in response to determining that the first UI element enters the target area, enabling the second UI element to be switched from a first state to a floating state, wherein a size or a background board style of the second UI element in the floating state is different from that of the second UI element in the first state; or
in response to determining that the first UI element leaves the target area, enabling the second UI element to exit the floating state.

19. The electronic device according to claim 11, the operations further comprising:
determining, based on a comparison between the target area and location information that is associated with the first UI element, that the first UI element enters or leaves the target area associated with the second UI element, wherein the location information indicates a central location or a boundary location of the first UI element.

20. A computer-readable storage medium, wherein the computer-readable storage medium stores instructions, and when the instructions are executed by an electronic device, the electronic device is enabled to perform the operations:
displaying a first user interface (UI) element and a second UI element on a screen of an electronic device;
in response to detecting an operation performed on the first UI element, enabling the first UI element to move; and
enabling, in response to determining that the first UI element enters or leaves a target area associated with the second UI element, at least one of the first UI element and the second UI element to produce an animation effect causing a change in the display, wherein a degree of the change is determined based at least on a first size of the first UI element or a second size of the second UI element.
